(19) United States
(12) Patent Application Publication
(10) Pub. No.: US 2025/0349811 A1
(43) Pub. Date: Nov. 13, 2025

(54) SEMICONDUCTOR MODULE INCLUDING A CORNER DIE OVER A SIDE OF A SEMICONDUCTOR DIE, PACKAGE STRUCTURE INCLUDING THE SEMICONDUCTOR MODULE AND METHODS OF FORMING THE SAME

(71) Applicant: Taiwan Semiconductor Manufacturing Company Limited, Hsinchu (TW)

(72) Inventors: Chen-Shien Chen, Zhubei City (TW); Chi-Yen Lin, Tainan City (TW); Hsu-Hsien Chen, Hsinchu City (TW); Pei Chun Tsai, Hsinchu City (TW); Feng-Chang Hsu, Hsinchu (TW)

(21) Appl. No.: 18/661,971

(22) Filed: May 13, 2024

(51) Int. Cl. H01L 25/18; H01L 23/00

(52) U.S. Cl. CPC H01L 25/18; H01L 24/08; H01L 24/32; H01L 24/80; H01L 24/83; H01L 2224/08145; H01L 2224/32145; H01L 2224/80895; H01L 2224/80896; H01L 2224/83895; H01L 2224/83896; H01L 2924/1815

(57) ABSTRACT

A semiconductor module includes a first semiconductor die, a second semiconductor die on the first semiconductor die, and a first corner die adjacent the second semiconductor die on the first semiconductor die and including a first corner die first side, a first corner die second side and a first corner die corner side connecting the first corner die first side and the first corner die second side, wherein the first corner die is located over a side of the first semiconductor die.

### BACKGROUND

A semiconductor module (e.g., three-dimensional semiconductor module) may often experience corner stress (e.g., mechanical stress) at a corner of the semiconductor module. Corner stress may lead to mechanical failures such as cracking or delamination in the semiconductor module. Corner stress may, therefore, diminish reliability and performance of the semiconductor module.

Several factors may contribute to the corner stress. In particular, the semiconductor module may contain materials with different coefficients of thermal expansion (CTE). When the semiconductor module undergoes temperature changes, the varying rates of expansion and contraction among these materials can lead to corner stress.

Corner stress may also be introduced, for example, by the process of stacking dies having different thermal properties, dimensions, warpage characteristics, etc., by the process steps in making the semiconductor module (e.g., bonding, molding, curing, etc.), by the design (e.g., shape, thickness, layout, etc.) of the semiconductor module, by using dies having inhomogeneous or mismatched material properties, by the method of attaching the semiconductor module to a package substrate and by the interconnects between the dies in the semiconductor module.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a semiconductor module according to one or more embodiments.

FIG. 1B is a plan view (e.g., top-down view) of the semiconductor module according to one or more embodiments.

FIG. 1C is a perspective view of the first semiconductor die, second semiconductor die and corner dies in the semiconductor module according to one or more embodiments.

FIG. 1D is a detailed vertical cross-sectional view of the semiconductor module according to one or more embodiments.

FIG. 2A is a vertical cross-sectional view of an intermediate structure in a process of fabricating the first semiconductor die according to one or more embodiments.

FIG. 2B is a vertical cross-sectional view of an intermediate structure in a process of fabricating the second semiconductor die according to one or more embodiments.

FIG. 2C is a vertical cross-sectional view of an intermediate structure in a process of fabricating the corner dies according to one or more embodiments.

FIG. 2D is a vertical cross-sectional view of an intermediate structure including the first semiconductor die on a first carrier substrate (e.g., first carrier wafer) according to one or more embodiments.

FIG. 2E is a vertical cross-sectional view of an intermediate structure including the first semiconductor die after planarization according to one or more embodiments.

FIG. 2F is a vertical cross-sectional view of an intermediate structure including the die bonding film according to one or more embodiments.

FIG. 2G is a vertical cross-sectional view of an intermediate structure including the second semiconductor die and corner dies according to one or more embodiments.

FIG. 2H is a vertical cross-sectional view of an intermediate structure including the second gap fill layer according to one or more embodiments.

FIG. 2I is a vertical cross-sectional view of an intermediate structure including the first passivation layer according to one or more embodiments.

FIG. 2J is a vertical cross-sectional view of an intermediate structure including the second passivation layer (e.g., polyimide layer) according to one or more embodiments.

FIG. 2K is a vertical cross-sectional view of an intermediate structure including the C4 bumps according to one or more embodiments.

FIG. 3 is a flow chart illustrating a method of making the semiconductor module according to one or more embodiments.

FIG. 4 is a vertical cross-sectional view of a package structure including the semiconductor module according to one more embodiments.

FIG. 5A is a plan view of the first corner die having a first corner die corner side with a convex shape (round shape, curved shape, semicircular shape, etc.) according to one or more embodiments.

FIG. 5B is a plan view of the first corner die having a first corner die corner side with a concave shape according to one or more embodiments.

FIG. 5C is a plan view of the first corner die having a first corner die corner side with a wavy shape (e.g., undulating shape) according to one or more embodiments.

FIG. 6A is a plan view of the first corner die having a first alternative design according to one or more embodiments.

FIG. 6B is a plan view of the first corner die having a second alternative design according to one or more embodiments.

FIG. 6C is a plan view of the first corner die having a third alternative design according to one or more embodiments.

FIG. 6D is a plan view of the first corner die having a fourth alternative design according to one or more embodiments.

FIG. 6E is a plan view of the first corner die having a fifth alternative design according to one or more embodiments.

FIG. 6F is a plan view of the first corner die having a sixth alternative design according to one or more embodiments.

FIG. 6G is a plan view of the first corner die having a seventh alternative design according to one or more embodiments.

FIG. 7A is a plan view of the first corner die 111 having a first alternative arrangement with the first semiconductor die 10 according to one or more embodiments.

FIG. 7B is a plan view of the first corner die 111 having a second alternative arrangement with the first semiconductor die 10 according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within the same thickness range.

Currently, in a semiconductor module including a first level with at least a first semiconductor die and a second level with at least a second semiconductor die and first corner die (e.g., first dummy die), an edge and corner of the second semiconductor die may align with an edge and corner of the first semiconductor die. An edge and corner of the first corner die may also align with an edge and corner of the first semiconductor die.

However, the semiconductor module may experience a crack failure in a passivation layer on the first semiconductor die. The crack failure may be caused, for example, by a shrinkage of the second semiconductor die and/or the first corner die. In particular, the rate of crack failures may increase (e.g., from 0.1% to 0.9%) with a shrinkage of the first corner die.

At least one embodiment of the present disclosure may include an innovative three-dimensional (3D) structure for corner stress relief in a semiconductor module (e.g., a system on integrated chips). The 3D structure may include a semiconductor module having a bottom die (first semiconductor die), and a top die (second semiconductor die) and a first corner die (e.g., dummy die) on the bottom die. A pattern design of the semiconductor module may improve corner stress.

The semiconductor module may include two or more second tier (T2) dies (e.g., semiconductor dies, system on a chip (SoC) dies, dummy dies, etc.) stacked on at least a first tier (T1) die (e.g., bottom semiconductor die). In at least one embodiment, the second semiconductor die edge and corner and/or first corner die edge and corner may be located over the first semiconductor die edge and corner. The second semiconductor die and/or first corner die may include corner rounding. The semiconductor module may also include one or more metal layers (e.g., metal pads, Al pads, etc. and a bonding film (e.g., SiO/SiN/SiON film).

In at least one embodiment, the second semiconductor die edge and corner and/or first corner die edge and corner may not be align with the first semiconductor die. This design may provide several advantages and benefits including a reduction in the risk of crack formation in a passivation layer (e.g., F-PASS2 crack). The embodiments may be applicable for multiple technology generations and can be expanded to other applications.

In at least one embodiment a corner/edge of the first semiconductor die may be smaller than the corner/edge of the second semiconductor die/first corner die (e.g., dummy die) for reducing a risk of F-PASS2 crack formation. In particular, an edge and corner of the second semiconductor die may be located over the edge and corner of the first semiconductor die, and/or an edge and corner of the first corner die (e.g., dummy die) may be located over the edge and corner of the first semiconductor die.

A process flow for making the semiconductor module may include 1) performing a plasma dicing to singulate the first semiconductor die (e.g., SOC(TD1) plasma dicing); 2) bonding the first semiconductor die to a first carrier substrate (e.g., CPU fusion bond and gap fill); 3) performing grinding or polishing (e.g., chemical mechanical polishing) to reveal through silicon via (TSV); 4) forming backside metal bumps (BSBPM) on a backside of the first semiconductor die; 5) performing plasma dicing (SOC dummy plasma dicing) to singulate corner dies (e.g., dummy dies) (this step can be done at any time up to this point); 6) bonding the second semiconductor die and the corner dies (e.g., dummy die) to the first semiconductor die (e.g., X3D hybrid bond/dummy fusion bond); and 7) forming a passivation layer on a passivation layer of the first semiconductor die and then forming a polyimide layer on the passivation layer.

In at least one embodiment, the second semiconductor die or first corner die (e.g., dummy die) may include a chamfer portion (e.g., corner side) having a chamfer length less than or equal to 7 μm, and a surface of the chamfer portion may have a line shape, round shape, wave shape, etc. In at least one embodiment, the second semiconductor die edge or first corner die edge may not align with the first semiconductor die (e.g., the first semiconductor die edge). In at least one embodiment, the second semiconductor die corner and edge or first corner die corner and edge may be located over the first semiconductor die. In at least one embodiment, the first semiconductor may include an active die or a passive device such as a deep trench capacitor (DTC). In at least one embodiment, each of the second semiconductor die and the first corner die may be over all of the corners of the first semiconductor die (e.g., all four corners of the first semiconductor die may be covered by the second semiconductor die and/or one or more of the first corner dies).

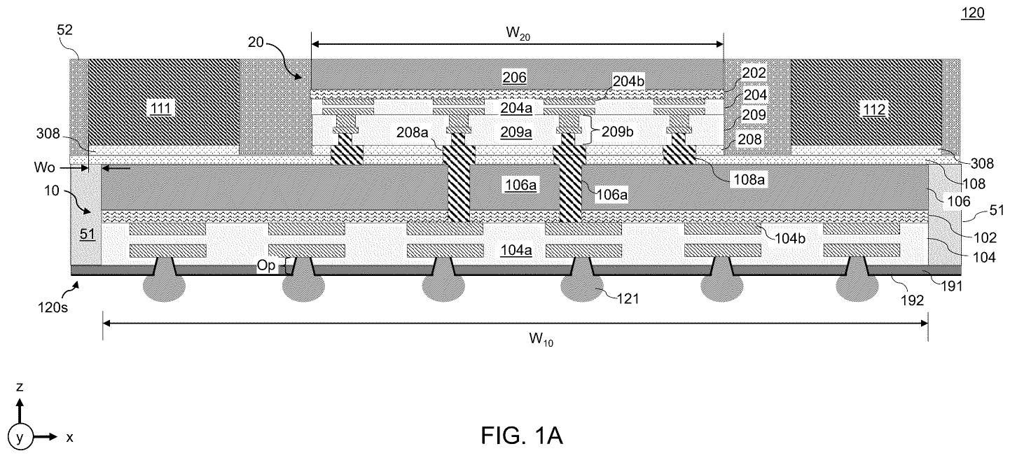

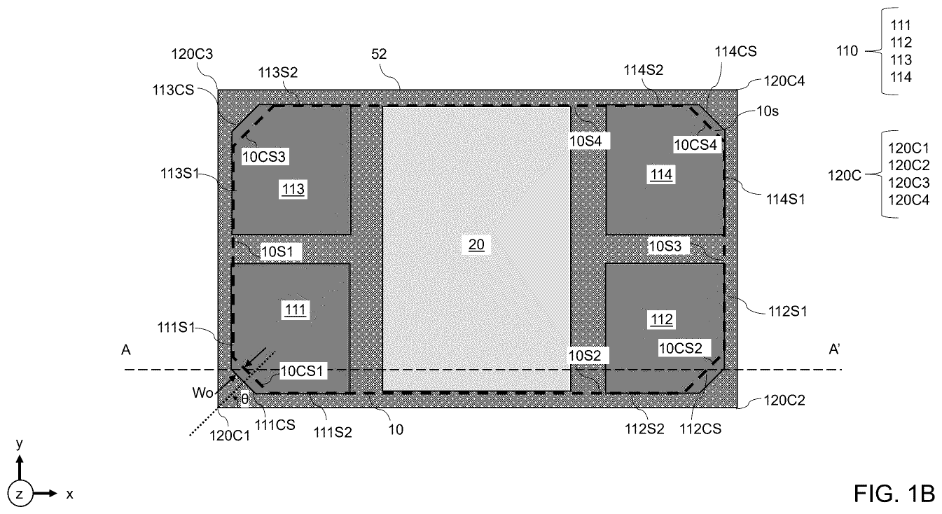

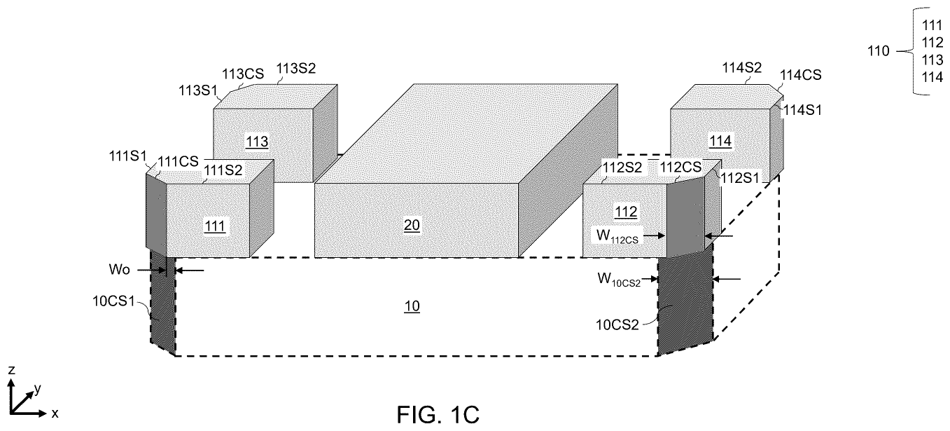

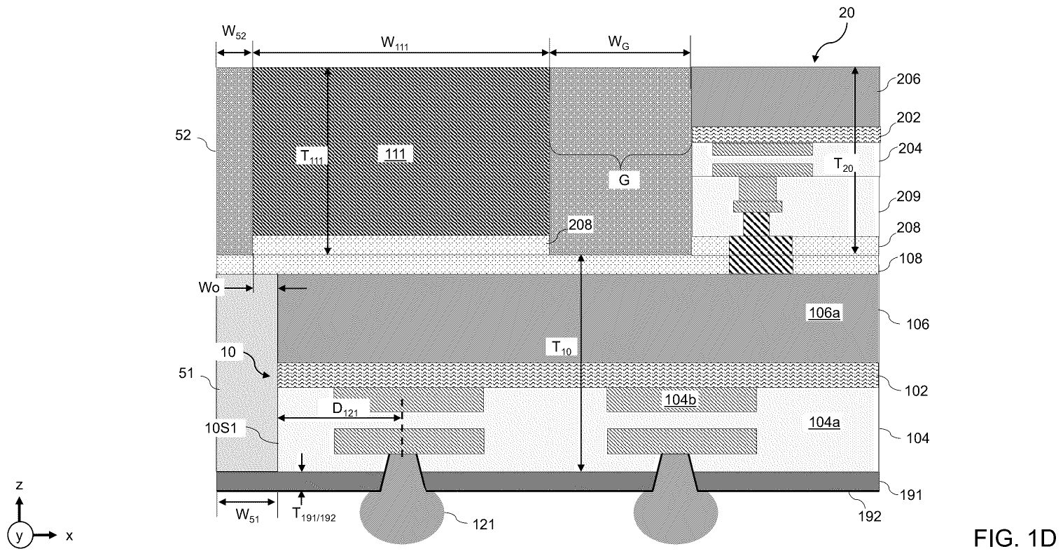

FIG. 1A is a vertical cross-sectional view of a semiconductor module 120 according to one or more embodiments. FIG. 1B is a plan view (e.g., top-down view) of the semiconductor module 120 according to one or more embodiments. The vertical cross-sectional view in FIG. 1A is along the line A-A′ in FIG. 1B. FIG. 1C is a perspective view of the first semiconductor die 10, second semiconductor die 20 and corner dies 110 in the semiconductor module 120 according to one or more embodiments. FIG. 1D is a detailed vertical cross-sectional view of the semiconductor module 120 according to one or more embodiments.

As illustrated in FIG. 1A, the semiconductor module 120 may include one or more first semiconductor dies 10 (e.g., bottom semiconductor dies, first level semiconductor dies, etc.) and one or more second semiconductor dies 20 (e.g., top semiconductor dies, second level semiconductor dies, etc.) on the first semiconductor die 10. The semiconductor module 120 may also include a first corner die 111 and a second corner die 112 on the first semiconductor die 10. As illustrated in FIG. 1B, the semiconductor module 120 may include one or more corner dies 110 including the first corner die 111, the second corner die 112, a third corner die 113 and a fourth corner die 114. At least one of the corner dies 110 may be located over a side of the first semiconductor die 10. That is, at least a portion of one or more of the corner dies 110 may be located outside the first semiconductor die 10 in a plan view (e.g., top-down view of the semiconductor module 120). In at least one embodiment, at least one of the corner dies 110 may overlap a side of the first semiconductor die 10 by an overlap distance Wo.

It should be noted that the term “corner” is not necessarily limited to a point where two sides intersect. The term “corner” may be construed to include a truncated corner that is formed by truncating a corner (e.g., a corner of a die). The truncated corner may not include a point of intersection of two sides, but instead include a corner side that connects the two sides.

It should also be noted that the phrase “side of the first semiconductor die 10” may be construed to mean over a sidewall (e.g., vertical sidewall) of the first semiconductor die 10 extending in the z-direction. In particular, a corner die 110 (111, 112) may be “over a side of the first semiconductor die 10” in instances in which the side of the first semiconductor die 10 exists in a plane (e.g., vertical plane) that intersects the corner die 110. A corner die 110 may be “over a side of the first semiconductor die 10” in instances in which at least some portion of the corner die 110 is located outside the first semiconductor die 10 in the x-direction and/or y-direction in the plan view.

Although the semiconductor module 120 is illustrated as including a particular number of semiconductor dies (10, 20) and corner dies 110, having a particular arrangement, the number of semiconductor dies (10, 20) and corner dies 110 and the arrangement of the semiconductor dies (10, 20) and corner dies 110 is not limited to any particular number and arrangement. In particular, the semiconductor module 120 may include any number and arrangement of semiconductor dies (10, 20) and corner dies 110. The semiconductor module 120 is also not limited to only two levels (e.g., two tiers) but may include any number of levels greater than one.

The first semiconductor die 10 and the second semiconductor die 20 may each have the same type or a different type. Each of the first semiconductor die 10 and the second semiconductor die 20 may include, for example, a singular semiconductor die, a system on chip (SOC) die, or a system on integrated chips (SoIC) die, and may be implemented by chip on wafer on substrate (CoWoS) technology or integrated fan-out on substrate (INFO-oS) technology. In particular, each of the semiconductor dies (10, 20) may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, an inverted AND (NAND) die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an integrated passive device (IPD) die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other semiconductor dies are within the contemplated scope of this disclosure.

In at least one embodiment, at least one of the semiconductor dies in the semiconductor module 120 may include a primary die (e.g., SOC die), and at least one of the semiconductor dies may include an ancillary die (e.g, memory/SOC die, HBM die, etc.).

As illustrated in FIG. 1A, the first semiconductor die 10 may include, for example, a front end of line (FEOL) region 102 including electronic circuitry including various electronic devices (e.g., transistors, resistors, etc.). In particular, the FEOL region 102 may include one or more logic circuits including logic devices (e.g., logic gates) and/or one or more memory circuits including memory devices (e.g., volatile memory (VM) devices and/or non-volatile memory (NVM) devices).

The first semiconductor die 10 may also include a back end of line (BEOL) region 104 (e.g., BEOL top metal structure) on the FEOL region 102. The BEOL region 104 may include interlayer dielectric 104a having one or more dielectric layers. The dielectric layers may include, for example, SiO₂, a dielectric polymer or other suitable dielectric material. The interlayer dielectric 104a may include one or more metal interconnect structures 104b formed therein. The metal interconnect structures 104b may include metal traces and metal vias formed in the dielectric layers and provide an electrical connection to the electronic circuitry in the FEOL region 102. The metal interconnect structures 104b may include one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The first semiconductor die 10 may also include a bulk semiconductor region 106 at the backside of the first semiconductor die 10. The bulk semiconductor region 106 may include a bulk semiconductor layer 106a. The bulk semiconductor layer 106a may include, for example, bulk silicon. Other suitable semiconductor materials are within the contemplated scope of disclosure. The bulk semiconductor region 106 may also include one more through vias 106b extending from a backside of the first semiconductor die 10 through the bulk semiconductor layer 106a and through the FEOL region 102 and contact a metal interconnect structure 104b in the BEOL region 104. The through vias 106b may include one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The semiconductor module 120 may also include a first gap fill layer 51 on the sides of the first semiconductor die 10. In at least one embodiment, the first gap fill layer 51 may be formed around an entire periphery of the first semiconductor die 10. In at least one embodiment, the first gap fill layer 51 may substantially encapsulate the first semiconductor die 10. The first gap fill layer 51 may include, for example, silicon oxide, silicon nitride or other suitable gap fill materials.

The semiconductor module 120 may also a die bonding film 108 (e.g., hybrid bonding film) at the backside of the first semiconductor die 10 and on the first gap fill layer 51. The die bonding film 108 may include an oxide such as silicon oxide. Other suitable bonding films are within the contemplated scope of disclosure.

One or more backside metal bonding pads 108a (e.g., backside bonding pad metal) may be located in the die bonding film 108 at the backside of the first semiconductor die 10 in the die bonding film 108. At least one of the backside metal bonding pads 108a may contact one of the through vias 106b in the bulk semiconductor region 106. The backside metal bonding pads 108a may, therefore, be electrically coupled to the metal interconnect structures 104b in the BEOL region 104 by the through vias 106b. The backside metal bonding pads 108a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The second semiconductor die 20 may be substantially the same as the first semiconductor die 10. In at least one embodiment, the second semiconductor die 20 may have a size that is less than a size of the first semiconductor die 10. In particular, the second semiconductor die 20 may have a second semiconductor die width W₂₀ less than a first semiconductor die width W₁₀ of the first semiconductor die 10. The second semiconductor die 20 may be attached to a central region of the first semiconductor die 10.

The second semiconductor die 20 may include an FEOL region 202 similar to the FEOL region 102 in the first semiconductor die 10 and a BEOL region 204 (BEOL top metal structure) similar to the BEOL region 104 in the first semiconductor die 10. The BEOL region 204 may include interlayer dielectric 204a and one or more metal interconnect structures 204b in the interlayer dielectric 204a. The second semiconductor die 20 may also include a bulk semiconductor region 206 (similar to the bulk semiconductor region 106) at the backside of the second semiconductor die 20.

The second semiconductor die 20 may also include an optional contact region 209 on the BEOL region 204 and opposite the FEOL region 202. The contact region 209 may have a structure based upon an individual customer design. The contact region 209 may include a dielectric material 209a. The dielectric material 209a may include, for example, SiO₂, a dielectric polymer or other suitable dielectric material. The contact region 209 may also include one or more contact structures 209b in the dielectric material 209a. Each of the contact structures 209b may include one or more metal layers and metal vias extending over the thickness of the dielectric material 209a.

The second semiconductor die 20 may also a second semiconductor die bonding film 208 (similar to the die bonding film 108) on the contact region 209 at the backside of the second semiconductor die 20. The second semiconductor die 20 may also include one or more frontside metal bonding pads 208a (similar to the backside metal bonding pads 108a) in the second semiconductor die bonding film 208. The frontside metal bonding pads 208a may, therefore, be electrically coupled to the metal interconnect structures 204b in the BEOL region 204 by the metal contact structures 209a.

The second semiconductor die 20 may be connected (e.g., attached) to the first semiconductor die 10 by a hybrid bond. The hybrid bond may include a metal-metal bond between the backside metal bonding pads 108a of the first semiconductor die 10 and the frontside metal bonding pads 208a of the second semiconductor die 20. The hybrid bond may also include a dielectric bond (e.g., oxide-oxide bond) between the die bonding film 108 and the second semiconductor die bonding film 208.

The corner dies 110 including the first corner die 111 and second corner die 112 may be attached to the first semiconductor die 10 adjacent the second semiconductor die 20. The corner dies 110 may include a corner die bonding film 308 similar to the die bonding film 108 and second semiconductor die bonding film 208. The corner die bonding film 308 may be bonded to the die bonding film 108. As illustrated in FIG. 1A, the first corner die 111 may be located over a side of the first semiconductor die 10 and the second corner die 112 may be located over an opposing side of the first semiconductor die 10. In particular, the corner dies 110 may overlap the corner and/or edge of the first semiconductor die 10 by the overlap distance Wo. In at least one embodiment, the overlap distance Wo may be greater than 1 μm.

The corner dies 110 may include, for example, a dummy die. The dummy die may include a non-functional or inactive component serving one or more purposes, such as filling space, providing mechanical support, managing thermal properties, or maintaining electrical symmetry. The dummy die may not be electrically active and may not contribute to a functional aspect of the semiconductor module 120.

The corner dies 110 may alternatively or additionally include one or more active devices (e.g., transistor) and/or one or more passive devices (e.g., deep trench capacitor). In at least one embodiment, the corner dies 110 may include a semiconductor die similar to the first semiconductor die 10 and second semiconductor die 20. In at least one embodiment, the corner dies 110 may have a structure and function similar to a structure and function of the first semiconductor die 10 and/or the second semiconductor die 20.

The semiconductor module 120 may also include a second gap fill layer 52. The second gap fill layer 52 may be formed on the die bonding film 108 and around the second semiconductor die 20 and the corner dies 110. A surface of the second gap fill layer 52 may be substantially coplanar with a surface of the second semiconductor die 20 and the corner dies 110. The second gap fill layer 52 may include an upper surface that is substantially uniform (e.g., flat). The upper surface of the second gap fill layer 52 may alternatively or additionally include a recessed portion (not shown) that is recessed in the z-direction from the upper surface of the second semiconductor die 20 and corner dies 110.

In at least one embodiment, the second gap fill layer 52 may be formed on sidewalls (inner sidewall and outer sidewall) of each of the second semiconductor die 20 and corner dies 110. The second gap fill layer 52 may be formed between and bonded to the sidewalls of each of the second semiconductor die 20 and corner dies 110. The second gap fill layer 52 may substantially encapsulate the second semiconductor die 20 and the corner dies 110. The second gap fill material layer 52 may also include, for example, silicon oxide, silicon nitride or other suitable gap fill materials.

The semiconductor module 120 may also include a first passivation layer 191 located at a board-side surface 120s of the first semiconductor die 10. The semiconductor module 120 may also include a second passivation layer 192 on the first passivation layer 191. The second passivation layer 192 may also have a thickness less than a thickness of the first passivation layer 191. An opening Op may be formed in the first passivation layer 191, second passivation layer 192 and dielectric material 104a so as to expose a surface of the metal interconnect structures 104b in the BEOL region 104.

The second passivation layer 192 may include a material different than a material of the first passivation layer 191. Each of the first passivation layer 191 and the second passivation layer 192 may include silicon oxide, silicon nitride, silicon oxynitride, low-k dielectric materials such as carbon-doped oxides, extremely low-k dielectric materials such as porous carbon doped silicon dioxide, a combination thereof or other suitable material. In at least one embodiment, the second passivation layer 192 may include a polyimide material.

As illustrated in FIG. 1A, the first passivation layer 191 and second passivation layer 192 may extend across substantially the entire board-side surface 120s of the semiconductor module 120. In this embodiment, the first gap fill layer 51 may be located on the first passivation layer 191 and second passivation layer 192 around an entirety of the semiconductor module 120. The first passivation layer 191 and second passivation layer 192 may alternatively be formed only on the BEOL region 104 of the first semiconductor die 10. In that case, the second gap fill layer 52 may be formed along a sidewall of the first semiconductor die 10, a sidewall of the first passivation layer 191 and a sidewall of the second passivation layer 192.

The semiconductor module 120 may also include one or more controlled collapse chi connection (C4) bumps 121 (also referred to as flip chip) connected to a board-side surface 120s of the semiconductor module 120. The C4 bumps 121 may be formed in the openings Op in the first passivation layer 191, second passivation layer 192 and dielectric material 104a so as to contact the surface of the metal interconnect structures 104b in the BEOL region 104.

In at least one embodiment, the C4 bumps 121 may include underbump metallurgy (UBM) layers (not shown) on the interposer lower bonding pads. The C4 bumps 121 may further include a contact pad (e.g., copper/nickel contact pad) on the UBM layers and a solder bump (e.g., SnAg solder bump) on the contact pad. The C4 bumps 121 may allow the semiconductor module 120 to be connected to a substrate such as a package substrate.

Referring again to FIG. 1B, a location of the first semiconductor die 10 is indicated in FIG. 1B by a dashed line. The semiconductor module 120 may have a generally rectangular shape in the plan view (e.g., top-down view). A longitudinal direction of the semiconductor module 120 may be in the x-direction. Other shapes are within the contemplated scope of disclosure.

As illustrated in FIG. 1B, the semiconductor module 120 may include a first semiconductor module corner 120C1, a second semiconductor module corner 120C2, a third semiconductor module corner 120C3 and a fourth semiconductor module corner 120C4 which may be referred to collectively as the semiconductor module corners 120C. One or more of the semiconductor module corners 120C may have the shape of a right angle. Other shapes are within the contemplated scope of disclosure.

The outer edge of the semiconductor module may be comprised of the first gap fill layer 51 and the second gap fill layer 52 (e.g., see FIG. 1A). The first gap fill layer 51 and second gap fill layer 52 may be formed around some or the entire periphery of the semiconductor module 120. Thus, the semiconductor module corners 120C may include corners of the first gap fill layer 51 and corners of the second gap fill layer 52.

The first semiconductor die 10 may have a shape substantially similar to the shape of the semiconductor module 120. The first semiconductor module 10 may also have a substantially rectangular shape with a longitudinal direction also in the same direction as the longitudinal direction of the semiconductor module 120 (e.g., the x-direction). Other shapes are within the contemplated scope of disclosure.

The first semiconductor die 10 may include a first semiconductor die first side 10S1, a first semiconductor die second side 10S2, a first semiconductor die third side 10S3 and a first semiconductor die fourth side 10S4. The first semiconductor die 10 may also include a first semiconductor die first corner side 10CS1 connecting the first semiconductor die first side 10S1 and the first semiconductor die second side 10S2, a first semiconductor die second corner side 10CS2 connecting the first semiconductor die second side 10S2 and the first semiconductor die third side 10S3, a first semiconductor die third corner side 10CS3 connecting the first semiconductor die first side 10S1 and the first semiconductor die fourth side 10S4, and a first semiconductor die fourth corner side 10CS4 connecting the first semiconductor die third side 10S3 and the first semiconductor die fourth side 10S4.

As illustrated in FIG. 1B, each of the first semiconductor die first corner side 10CS1, first semiconductor die second corner side 10CS2, first semiconductor die third corner side 10CS3 and first semiconductor die fourth corner side 10CS4 may include a truncated corner of the first semiconductor die 10. Further, each of the first semiconductor die first corner side 10CS1, first semiconductor die second corner side 10CS2, first semiconductor die third corner side 10CS3 and first semiconductor die fourth corner side 10CS4 may include a chamfered shape (e.g., formed of a straight line between two sides). Other shapes (e.g., concave shape, convex shape, wavy shape, etc.) are within the contemplated scope of disclosure. In at least one embodiment, at least one of the first semiconductor die first corner side 10CS1, first semiconductor die second corner side 10CS2, first semiconductor die third corner side 10CS3 and first semiconductor die fourth corner side 10CS4 may include a right angle corner instead of a truncated corner of the first semiconductor die 10.

As further illustrated in FIG. 1B, the second semiconductor die 20 may also have a substantially rectangular shape with a longitudinal direction in the y-direction (e.g., perpendicular to the longitudinal direction of the semiconductor module 120 and perpendicular to the longitudinal direction of the first semiconductor die 10). Other shapes are within the contemplated scope of disclosure.

A length of the second semiconductor die 20 in the y-direction may be substantially the same as a length of the first semiconductor die 10 in the y-direction in the central region of the first semiconductor die 10. The second semiconductor die 20 may include an edge substantially aligned with the first semiconductor die second side 10S2 and an edge substantially aligned with the first semiconductor die fourth side 10S4. The second semiconductor die 20 may alternatively or additionally include an edge that is misaligned with the first semiconductor die second side 10S2 and/or an edge that is aligned with the first semiconductor die fourth side 10S4. In at least one embodiment, the second semiconductor die 20 may include an edge that overlaps the first semiconductor die second side 10S2 and/or an edge that overlaps the first semiconductor die fourth side 10S4.

The corner dies 110 may be located on the first semiconductor die 10 adjacent the second semiconductor die 20. At least one of the corner dies 110 (e.g., first corner die 111, second corner die 112, third corner die 113 and fourth corner die 114) may be located over a side of the first semiconductor die 10. That is, at least a portion of at least one of the corner dies 110 may be located outside the first semiconductor die 10 (e.g., extend in the x-direction and/or y-direction beyond a side of the first semiconductor die 10 in the plan view). In at least one embodiment, all of the corner dies 110 may be located over a side of the first semiconductor die 10.

The first corner die 111 may include a first corner die first side 111S1, a first corner die second side 111S2 and a first corner die corner side 111CS connecting the first corner die first side 111S1 and the first corner die second side 111S2. The second corner die 112 may include a second corner die first side 112S1, a second corner die second side 112S2 and a second corner die corner side 112CS connecting the second corner die first side 112S1 and the second corner die second side 112S2. The third corner die 113 may include a third corner die first side 113S1, a third corner die second side 113S2 and a third corner die corner side 113CS connecting the third corner die first side 113S1 and the third corner die second side 113S2. The fourth corner die 114 may include a fourth corner die first side 114S1, a fourth corner die second side 114S2 and a fourth corner die corner side 114CS connecting the fourth corner die first side 114S1 and the fourth corner die second side 114S2.

As illustrated in FIG. 1B, some of the sides of the corner dies 110 may be substantially aligned with the respective sides of the first semiconductor die 10. In particular, with respect to the first corner die 111, the first corner die first side 111S1 may be substantially aligned with the first semiconductor die first side 10S1, and the first corner die second side 111S2 may be substantially aligned with the first semiconductor die second side 10S2. With respect to the second corner die 112, the second corner die first side 112S1 may be substantially aligned with the first semiconductor die third side 10S3, and the second corner die second side 112S2 may be substantially aligned with the first semiconductor die second side 10S2. With respect to the third corner die 113, the third corner die first side 113S1 may be substantially aligned with the first semiconductor die first side 10S1, and the third corner die second side 113S2 may be substantially aligned with the first semiconductor die fourth side 10S4. With respect to the fourth corner die 114, the fourth corner die first side 114S1 may be substantially aligned with the first semiconductor die third side 10S3, and the fourth corner die second side 114S2 may be substantially aligned with the first semiconductor die fourth side 10S4. The sides of the corner dies 110 may alternatively or additionally be misaligned with the sides of the first semiconductor die 10 (e.g., located inside or outside the sides of the first semiconductor die 10).

As further illustrated in FIG. 1B, at least one of the corner dies 110 may be located over a side of the first semiconductor die 10. In particular, at least one of the corner sides of the corner dies 110 may be located outside the respective corner side of the first semiconductor die 10. This design may help to alleviate a corner stress at a respective one of the semiconductor module corners 120C.

In at least one embodiment, all of the corner dies 110 may be located over a side of the first semiconductor die 10 because all of the corner sides of the corner dies 110 may be located outside the respective corner side of the first semiconductor die 10. In particular, the first corner die corner side 111CS may be located outside the first semiconductor die first corner side 10CS1, the second corner die corner side 112CS may be located outside the first semiconductor die second corner side 10CS2, the third corner die corner side 113CS may be located outside the first semiconductor die third corner side 10CS3 and the fourth corner die corner side 114CS may be located outside the first semiconductor die fourth corner side 10CS4. This design may help to alleviate a corner stress at all of the semiconductor module corners 120C.

Each of the first corner die corner side 111CS, second corner die corner side 112CS, third corner die corner side 113CS and fourth corner die corner side 114CS may include a truncated corner. Further, each of the first corner die corner side 111CS, second corner die corner side 112CS, third corner die corner side 113CS and fourth corner die corner side 114CS may include a chamfered shape (e.g., formed of a straight line between two sides). Other shapes (e.g., concave shape, convex shape, wavy shape, etc.) are within the contemplated scope of disclosure.

Further, a shape of the first corner die corner side 111CS, second corner die corner side 112CS, third corner die corner side 113CS and fourth corner die corner side 114CS may be the same as or different than a shape of the respective corner side of the first semiconductor die 10. Thus, for example, a shape of the first corner die corner side 111CS may be the same as or different than a shape of the first semiconductor die first corner side 10CS1, a shape of the second corner die corner side 112CS may be the same as or different than a shape of the first semiconductor die second corner side 10CS2, and so on.

In at least on embodiment, a corner side of at least one of the corner dies 110 (e.g., first corner die corner side 111CS, second corner die corner side 112CS, etc.) may include a chamfered shape having a width less than or equal to 7 μm. In at least one embodiment, at least one corner side of the corner dies 110 may include a chamfered shape and a respective corner side of the first semiconductor die 10 may include a chamfered shape. As illustrated in FIG. 1B, in at least one embodiment, all corner sides of the corner dies 110 and all of the respective corner sides of the first semiconductor die 10 may include a chamfered shape.

In at least one embodiment, a plane of a corner side of the corner dies 110 may be substantially parallel with a plane of a respective corner side of the first semiconductor die 10. Thus, for example, a plane of the first corner die corner side 111CS may be substantially parallel with a plane of the first semiconductor die first corner side 10CS1, a plane of the second corner die corner side 112CS may be substantially parallel with a plane of the first semiconductor die second corner side 10CS2, and so on.

In at least one embodiment, a corner side of the corner dies 110 may be located outside the respective corner side of the first semiconductor die 10 and an overlap distance between the corner side and the respective corner side of the first semiconductor die 10 may be greater than 1 μm. Thus, for example, the first corner die corner side 111CS may be located outside the first semiconductor die first corner side 10CS1 and an overlap distance between the first corner die corner side 111CS and the first semiconductor die first corner side 10CS1 may be greater than 1 μm.

In at least one embodiment, a corner side of the corner dies 110 may be located inside the respective corner side of the first semiconductor die 10 and an overlap distance Wo between the corner side of the corner die 110 and the respective corner side of the first semiconductor die 10 may be less than 1000 μm. Thus, for example, the first corner die corner side 111CS may be located inside the first semiconductor die first corner side 10CS1 and an overlap distance Wo between the first corner die corner side 111CS and the first semiconductor die first corner side 10CS1 may be less than 1000 μm.

In at least one embodiment, a corner side of a corner die 110 may be located outside the respective corner side of the first semiconductor die 10 and at least one of a first side of the corner die 110 may be located outside a respective side of the first semiconductor die 10, or a second side of the corner die 110 may be located outside the respective side of the first semiconductor die 10. Thus, for example, the first corner die corner side 111CS may be located outside the first semiconductor die first corner side 10CS1 and at least one of the first corner die first side 111S1 may be located outside the first semiconductor die first side 10S1, or the first corner die second side 111S2 may be located outside the first semiconductor die second side 10S2.

In at least one embodiment, a corner side of a corner die 110 may be substantially aligned with the respective corner side of the first semiconductor die 10 and at least one of a first side of the corner die 110 may be located outside the respective side of the first semiconductor die 10, or a second side of the corner die 110 may be located outside the respective side of the first semiconductor die 10. Thus, for example, the first corner die corner side 111CS may be substantially aligned with the first semiconductor die first corner side 10CS1 and at least one of the first corner die first side 111S1 may be located outside the first semiconductor die first side 10S1, or the first corner die second side 111S2 may be located outside the first semiconductor die second side 10S2.

Further, a corner side of the corner die 110 and the respective corner side of the first semiconductor die 10 may be substantially aligned with the respective corner of the semiconductor module 120. In particular, as indicated by the dotted line in FIG. 1B, a line intersecting a corner (e.g., right angle corner) of the semiconductor module 120 (e.g., first semiconductor module corner 120C1, second semiconductor module corner 120C2, third semiconductor module corner 120C3, or fourth semiconductor module corner 120C4) so as to divide the corner into equal 45° portions (θ=45°) may also intersect a center point of the corner side of the corner die 110 (e.g., 111CS in FIG. 1B) and intersect a center point of the respective corner side of the first semiconductor die 10 (e.g., 10CS1 in FIG. 1B).

Referring again to FIG. 1C, a width of a corner side of a corner die 110 may be substantially uniform in the z-direction (e.g., thickness direction) or may vary over the z-direction. A width of a corner side of the first semiconductor die 10 may also be substantially uniform in the z-direction or may vary over the z-direction.

In at least one embodiment, a width of a corner side of a corner die 110 may be less than a width of a respective corner side of the first semiconductor die 10. Thus, for example, in FIG. 1C, a width W_{112CS} of the second corner die corner side 112CS may be less than a width W_{10CS2} of the first semiconductor die second corner side 10CS2. In at least one embodiment, the width of the corner side of a corner die 110 may be in a range from 30% to 90% of the width of a respective corner side of the first semiconductor die 10.

Referring to FIG. 1D, the first corner die 111 is illustrated along with a portion of the first semiconductor die 10 and a portion of the second semiconductor die 20. Although only the first corner die 111 is illustrated in FIG. 1D, the description with respect to the first corner die 111 may be applicable to all of the corner dies 110 in the semiconductor module 120 (e.g., see FIGS. 1B and 1C).

The first semiconductor die 10 may have a first semiconductor die thickness T₁₀. The second semiconductor die 20 may have a second semiconductor die thickness T₂₀. The second semiconductor die thickness T₂₀ may be substantially the same as the first semiconductor die thickness T₁₀. In at least one embodiment, the second semiconductor die thickness T₂₀ may be greater than or less than the first semiconductor die thickness T₁₀. The first corner die 111 may have a first corner die thickness T₁₁₁ substantially the same as the second semiconductor die thickness T₂₀. In at least one embodiment, the first corner die thickness T₁₁₁ may be greater than or less than the second semiconductor die thickness T₂₀.

In at least one embodiment, at least one of the C4 bumps 121 may be located under the first corner die 111. In at least one embodiment, a lateral distance D121 between the first semiconductor die first side 10S1 and a center of the C4 bump 121 nearest the first semiconductor die first side 10S1 may be in a range from 500 μm to 3000 μm.

The first corner die 111 may be separated from the second semiconductor die 20 in the x-direction by a gap G. The gap G may have a gap width W_{G} in the x-direction. The first corner die 111 may have a first corner die width W₁₁₁ in the x-direction. The first corner die width W₁₁₁ may be greater than the gap width W_{G}. The first corner die width W₁₁₁ may be less than the second semiconductor die width W₂₀. The overlap distance Wo may be in a range from 1% to 30% of W₁₁₁.

The first gap fill layer 51 may have a width W₅₁ around the outer periphery of the semiconductor module 120 (e.g., adjacent the first semiconductor die first side 10S1). The second gap fill layer 52 may have a width W₅₂ around an outer perimeter of the semiconductor module 120 (e.g., adjacent the first corner die first side 111S1). In at least one embodiment, the width W₅₁ may be greater than the width W₅₂. In at least one embodiment (e.g., when a corner side of a corner die 110 is located inside the corner side of the first semiconductor die 10), the width W₅₁ may be less than or equal to the width W₅₂.

As illustrated in FIG. 1D, the first gap fill layer 51 may be formed adjacent the first semiconductor die 10 on the first passivation layer 191 and the second passivation layer 192. The first passivation layer 191 and the second passivation layer 192 may have a combined thickness T_{191/192} less than the first semiconductor die thickness T₁₀. The overlapping portion of the first corner die 111 (e.g., the portion formed outside the first semiconductor die 10) may be located over the first passivation layer 191 and the second passivation layer 192.

The first passivation layer 191 and the second passivation layer 192 may alternatively have a sidewall substantially aligned with a side of the first semiconductor die 10 (e.g., aligned with the first semiconductor die first side 10S1). In that case, the first gap fill layer 51 may be formed along the sidewall of the first passivation layer 191 and the second passivation layer 192, and the overlapping portion of the first corner die 111 may not overlap any portion of the first passivation layer 191 and second passivation layer 192.

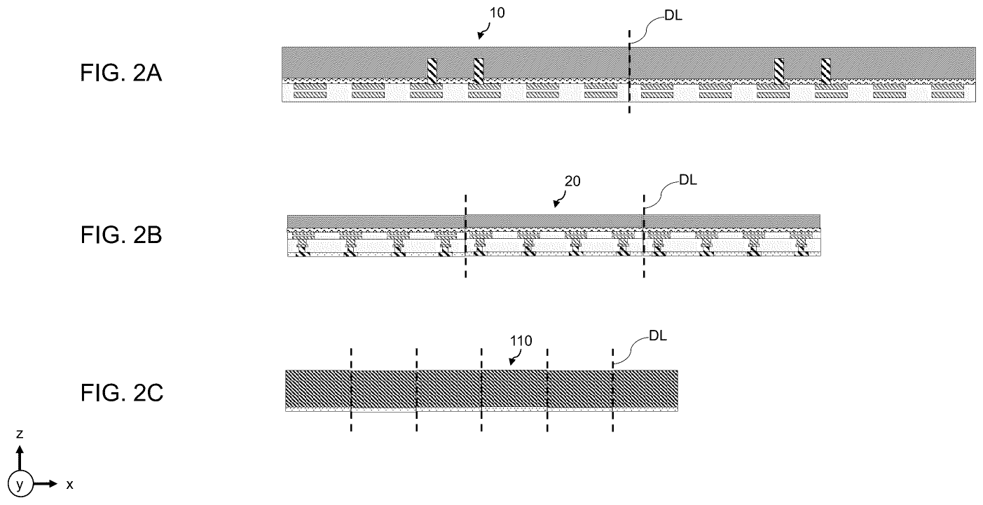

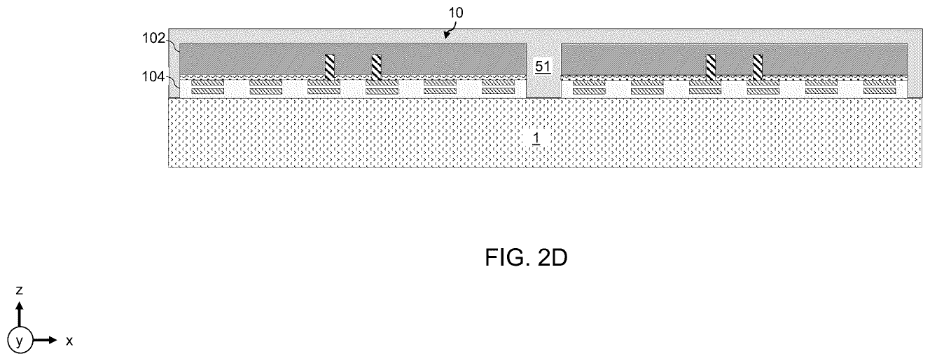

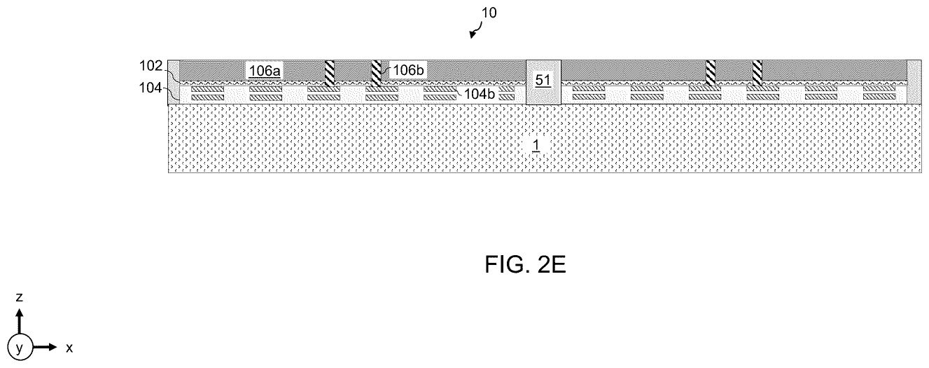

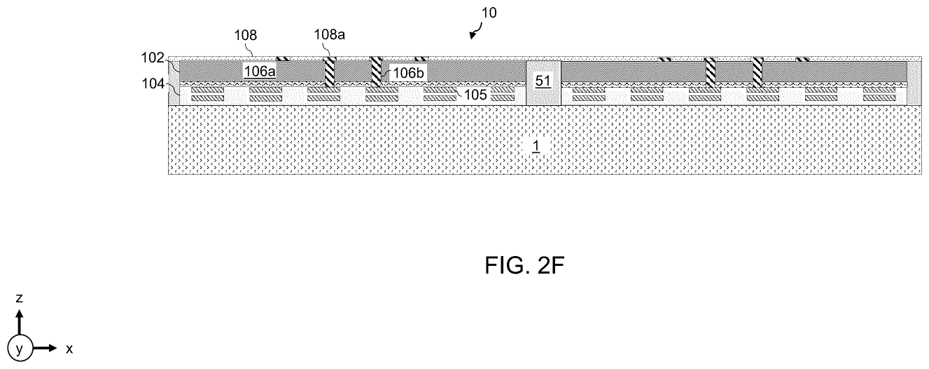

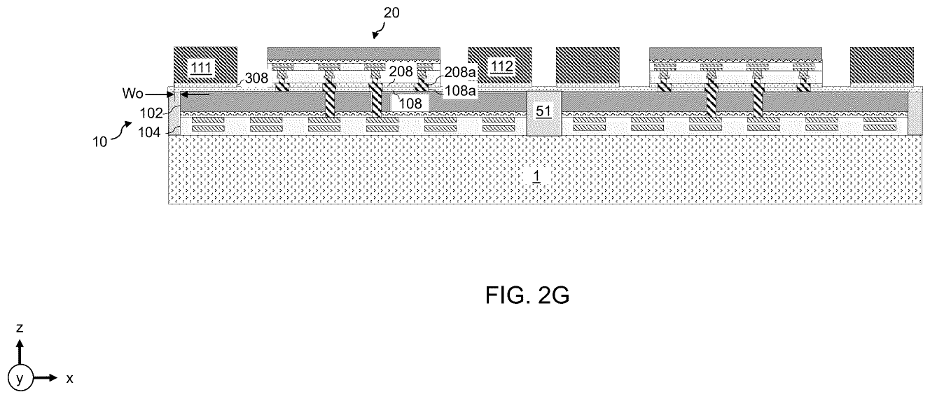

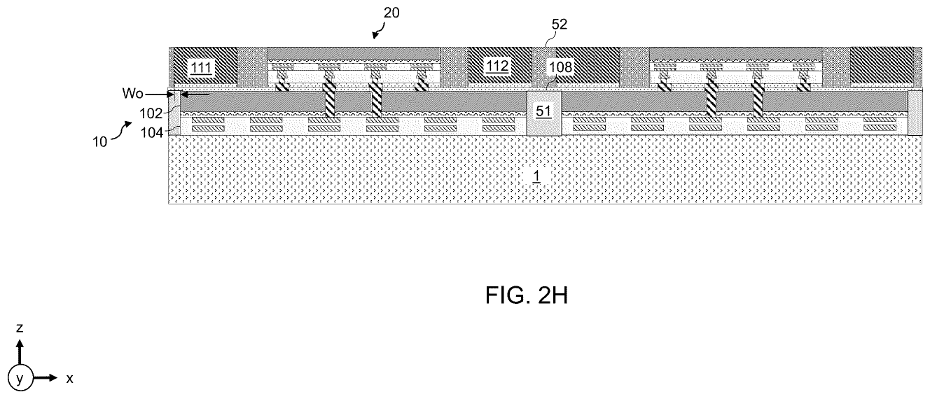

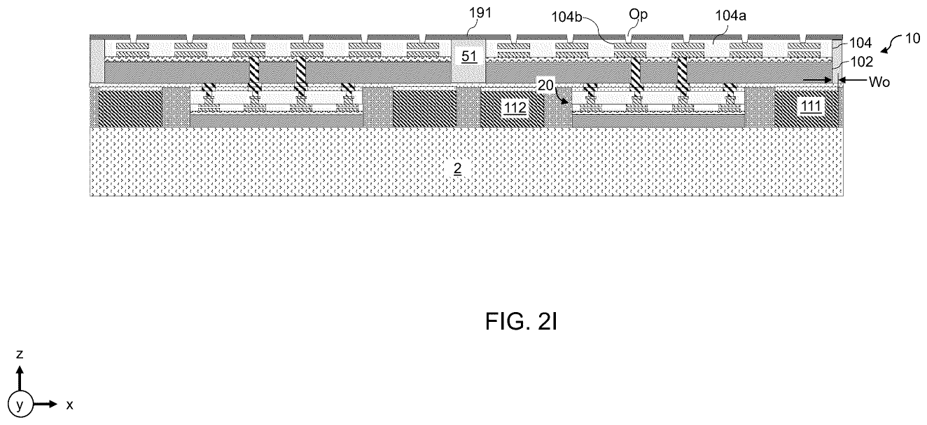

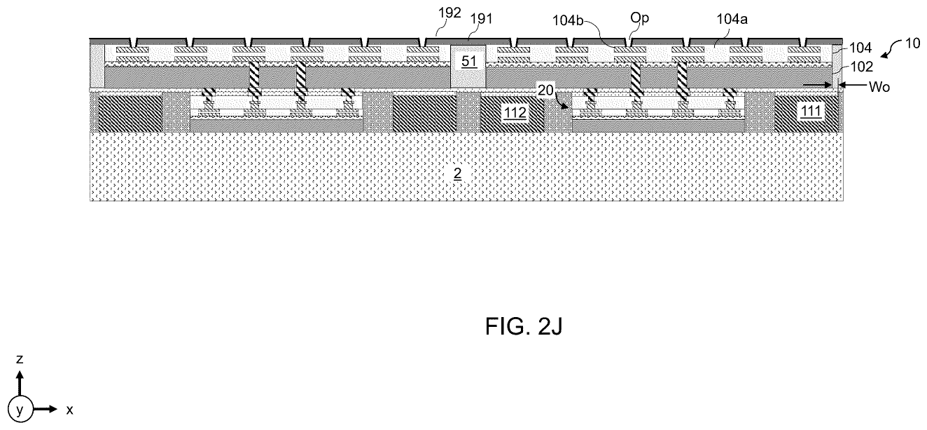

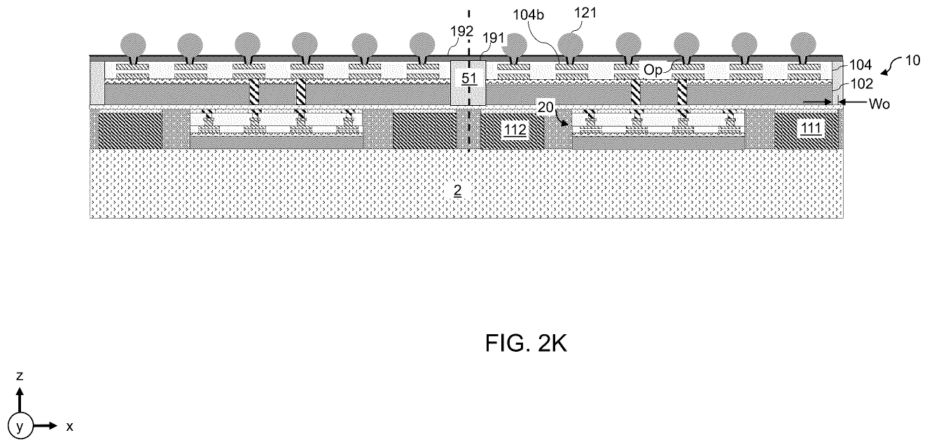

FIGS. 2A-2K are vertical cross-sectional views of various intermediate structures in a method of making the semiconductor module 120 according to one or more embodiments.

FIG. 2A is a vertical cross-sectional view of an intermediate structure in a process of fabricating the first semiconductor die 10 according to one or more embodiments. The intermediate structure is identified as first semiconductor 10 in FIG. 2A for ease of understanding. As illustrated in FIG. 2A, a plurality of the intermediate structures may be formed together on a single wafer in a wafer level process. The intermediate structures may then be singulated into individual units by performing a dicing process (e.g., plasma dicing process). In the dicing process, a dicing saw may cut along the dicing lines DL to singulate the first semiconductor dies 10 into individual units.

FIG. 2B is a vertical cross-sectional view of an intermediate structure in a process of fabricating the second semiconductor die 10 according to one or more embodiments. As illustrated in FIG. 2B, a plurality of the second semiconductor dies 20 may be formed together on a single wafer in a wafer level process. The second semiconductor dies 20 may then be singulated into individual units by performing a dicing process in which a dicing saw may cut along the dicing lines DL to singulate the second semiconductor dies 20 into individual units.

FIG. 2C is a vertical cross-sectional view of an intermediate structure in a process of fabricating the corner dies 110 according to one or more embodiments. As illustrated in FIG. 2C, a plurality of the corner dies 110 may be formed together on a single wafer in a wafer level process. The corner dies 110 may then be singulated into individual units by performing a dicing process in which a dicing saw may cut along the dicing lines DL to singulate the corner dies 110 into individual units.

FIG. 2D is a vertical cross-sectional view of an intermediate structure including the first semiconductor die 10 on a first carrier substrate 1 (e.g., first carrier wafer) according to one or more embodiments. As illustrated in FIG. 2D, the first semiconductor die 10 may be attached to the first carrier substrate 1 with the BEOL region 104 facing the first carrier substrate 1.

The first carrier substrate 1 may include a circular wafer or a rectangular wafer. The lateral dimensions (such as the diameter of a circular wafer or a side of a rectangular wafer) of the first carrier substrate 1 may be in a range from 100 mm to 500 mm, such as from 200 mm to 400 mm, although lesser and greater lateral dimensions may also be used. The first carrier substrate 1 may include a semiconductor substrate, an insulating substrate, or a conductive substrate. The first carrier substrate 1 may be transparent or opaque. A thickness of the first carrier substrate 1 may be sufficient to provide mechanical support to an array of interposers to be formed thereupon. For example, the thickness of the first carrier substrate 1 may be in a range from 60 μm to 1 mm, although lesser and greater thicknesses may also be used.

In at least one embodiment, the first semiconductor die 10 may be fusion bonded to the first carrier substrate 1. In at least one embodiment, an adhesive layer (not shown) may be applied to the top surface of the first carrier substrate 1. In one embodiment, the first carrier substrate 1 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. For example, the LTHC layer may include commercially available LTHC layers. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

After the first semiconductor die 10 is attached to the first carrier substrate 1, the first gap fill layer 51 may be formed in gaps adjacent the first semiconductor die 10. The first gap fill layer 51 may be formed, for example, by depositing gap fill material (e.g., silicon oxide, silicon nitride, etc.) by chemical vapor deposition (CVD), physical vapor deposition (PVD) or other suitable process.

FIG. 2E is a vertical cross-sectional view of an intermediate structure including the first semiconductor die 10 after planarization according to one or more embodiments. As illustrated in FIG. 2E, after the first gap fill layer 51 is formed a planarization process may be performed on an upper surface of the intermediate structure. The planarization process may be used to make a surface of the bulk semiconductor layer 106a and a surface of the first gap fill layer 51 coplanar with a surface of the through vias 106b. The planarization process may be performed until a surface of the through vias 106b is exposed (e.g., revealed).

A thickness of the bulk semiconductor layer 106a and a thickness of the first gap fill layer 51 may be reduced in the planarization process. In at least one embodiment, a thickness of the through vias 106b may be reduced in the planarization process. The planarization process may be performed, for example, by mechanical grinding, chemical mechanical polishing (CMP) or other suitable planarization process.

FIG. 2F is a vertical cross-sectional view of an intermediate structure including the die bonding film 108 according to one or more embodiments. As illustrated in FIG. 2F, the backside metal bonding pads 108a may be formed on the backside of the first semiconductor die 10.

A metal layer may be formed on the surface of the bulk semiconductor region 106 including on the bulk semiconductor layer 106a and on the through vias 106b.

The metal layer may then be patterned by a photolithographic process to form the backside metal bonding pads 108a. The photolithographic process may include forming a patterned photoresist mask (not shown) on the metal layer, and etching (e.g., wet etching, dry etching, etc.) the exposed upper surface of the metal layer through openings in the photoresist mask to form the backside metal bonding pads 108a. The photoresist mask may be subsequently removed by ashing, dissolving the photoresist mask or by consuming the photoresist mask during the etch process.

After the backside metal bonding pads 108a are formed, the die bonding film 108 may be formed on the first semiconductor die 10 and the first gap fill layer 51. The die bonding film 108 may also cover the backside metal bonding pads 108a. The die bonding film 108 may be formed, for example, by CVD, PVD or other suitable process. After the die bonding film 108 is formed, a planarization process may be performed to make a surface of the die bonding film 108 substantially coplanar with a surface of the backside metal bonding pads 108a. The planarization process may be performed, for example, by mechanical grinding, CMP or other suitable planarization process.

FIG. 2G is a vertical cross-sectional view of an intermediate structure including the second semiconductor die 20 and corner dies 110 according to one or more embodiments. As illustrated in FIG. 2G, after the die bonding film 108 is formed, the second semiconductor die 20 and corner dies 110 may be attached to the first semiconductor die 10 through the die bonding film 108.

The second semiconductor die 20 may be positioned on the first semiconductor die 10, for example, using an electromechanical pick-and-place (PNP) machine. The second semiconductor die 20 may be lowered onto the first semiconductor die 10 so that the frontside metal bonding pads 208a of the second semiconductor die 20 contact the backside metal bonding pads 108a of the first semiconductor die 10, and the second semiconductor die bonding film 208 contacts the die bonding film 108.

The second semiconductor die 20 may then be bonded to the first semiconductor die 10 by performing a hybrid bond process to form a hybrid bond (e.g., X3D hybrid bond). The hybrid bonding process may include application of heat and pressure to the second semiconductor die 20 to form the hybrid bond. The hybrid bond may include a metal-metal bond between the backside metal bonding pads 108a and the frontside metal bonding pads 208a, and a dielectric bond between the die bonding film 108 and the second semiconductor die bonding film 208.

The corner die bonding film 308 on the corner dies 110 (e.g., first corner die 111 and second corner die 112) may then be bonded to the die bonding film 108. In at least one embodiment, the corner dies 110 may be bonded to the die bonding film 108 by a fusion bond. The corner dies 110 may also be positioned on the first semiconductor die 10, for example, using an electromechanical pick and place (PNP) machine. The corner dies 110 may be positioned so as to overlap the corner and/or edge of the first semiconductor die 10 by the overlap distance Wo greater than 1 μm. The corner dies 110 may then be lowered onto the first semiconductor die 10 so that the corner die bonding film 308 contacts the die bonding film 108. Heat and pressure may then be applied to form the fusion bond.

FIG. 2H is a vertical cross-sectional view of an intermediate structure including the second gap fill layer 52 according to one or more embodiments. As illustrated in FIG. 2H, the second gap fill layer 52 may be formed so as to fill the gaps between the second semiconductor die 20 and the corner dies 110.

After the second semiconductor die 10 and corner dies 110 are attached to the first semiconductor die 10, the second gap fill layer 52 may be formed in gaps between the second semiconductor die 20 and the corner dies 110. The second gap fill layer 52 may be formed around the second semiconductor die 20 and the corner dies 110 on the die bonding film 108. The second gap fill layer 52 may be formed, for example, by depositing gap fill material (e.g., silicon oxide, silicon nitride, etc.) by CVD, PVD or other suitable process. After the second gap fill layer 52 is formed, a planarization process may be performed on an upper surface of the intermediate structure. The planarization process may be used to make a surface of the second gap fill layer 52 substantially coplanar with a surface of the second semiconductor die 10 and a surface of the corner dies 110. The planarization process may be performed, for example, by mechanical grinding, chemical mechanical polishing (CMP) or other suitable planarization process.

FIG. 2I is a vertical cross-sectional view of an intermediate structure including the first passivation layer 191 according to one or more embodiments. As illustrated in FIG. 2I, after the second gap fill layer 52 is formed and planarized, a second carrier substrate 2 may be attached to the planarized surface of the second gap fill layer 52, the second semiconductor die 20 and the corner dies 110. The second carrier substrate 2 may be substantially similar to the first carrier substrate 1.

The intermediate structure may then be inverted and the first carrier substrate 1 may be detached from the intermediate structure. The first carrier substrate 1 may be detached from the intermediate structure for example, by deactivating the adhesive layer (not shown) adhering the first carrier substrate 1 to the intermediate device. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

After the first carrier substrate 1 is detached from the intermediate structure, the first passivation layer 191 may be formed on the BEOL region 104 of the first semiconductor die 10 and on the first gap fill layer 51. To form the first passivation layer 191, a layer of passivation material may be deposited on the BEOL region 104 and on the first gap fill layer 51. The layer of passivation material may be formed by CVD, PVD, wet coating process, or other suitable deposition technique.

The passivation material may then be patterned by a photolithographic process to form the openings Op in the first passivation layer 191 and in the interlayer dielectric 104a of the BEOL region 104. The openings Op may be formed so as to expose a surface of the metal interconnect structures 104b in the BEOL region 104. The photolithographic process may include forming a patterned photoresist mask (not shown) on the passivation material, and etching (e.g., wet etching, dry etching, etc.) the exposed upper surface of the passivation material through openings in the photoresist mask to form the openings Op. The photoresist mask may be subsequently removed by ashing, dissolving the photoresist mask or by consuming the photoresist mask during the etch process.

FIG. 2J is a vertical cross-sectional view of an intermediate structure including the second passivation layer 192 (e.g., polyimide layer) according to one or more embodiments. As illustrated in FIG. 2J, the second passivation layer 192 may be formed on the first passivation layer 191 and in the openings Op in the first passivation layer 191 and the interlayer dielectric 104a of the BEOL region 104.

The second passivation layer 192 may be formed by depositing a layer of passivation material on the first passivation layer 191 and on a sidewall of the openings Op. In particular, the second passivation layer 192 may be deposited on the sidewall of the openings Op while maintaining an exposed surface of the metal interconnect structures 104b at a bottom of the openings Op. The layer of passivation material may be deposited by CVD, PVD, wet coating process, or other suitable deposition technique.

FIG. 2K is a vertical cross-sectional view of an intermediate structure including the C4 bumps 121 according to one or more embodiments. The C4 bumps 121 may include, for example, solder bumps formed in the openings Op. The C4 bumps 121 may be formed by one or more processes including ball mounting, electroplating, solder printing, solder immersion and solder injection. The C4 bumps 121 may contact the metal interconnect structures 104b in the BEOL region 104. In at least one embodiment, the C4 bumps 121 may be formed by forming one or more underbump metallization (UBM) layers (not shown) on the metal interconnect structures 104b.

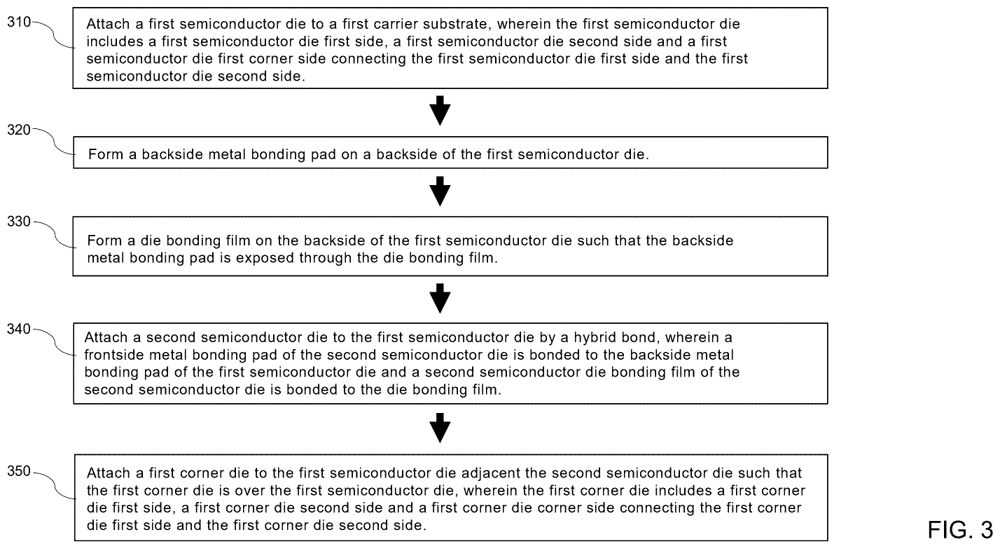

FIG. 3 is a flow chart illustrating a method of making the semiconductor module 120 according to one or more embodiments. Step 310 includes attaching a first semiconductor die to a first carrier substrate, wherein the first semiconductor die includes a first semiconductor die first side, a first semiconductor die second side and a first semiconductor die first corner side connecting the first semiconductor die first side and the first semiconductor die second side. Step 320 includes forming a backside metal bonding pad on a backside of the first semiconductor die. Step 330 includes forming a die bonding film on the backside of the first semiconductor die such that the backside metal bonding pad is exposed through the die bonding film. Step 340 includes attaching a second semiconductor die to the first semiconductor die by a hybrid bond, wherein a frontside metal bonding pad of the second semiconductor die is bonded to the backside metal bonding pad of the first semiconductor die and a second semiconductor die bonding film of the second semiconductor die is bonded to the die bonding film. Step 350 includes attaching a first corner die to the first semiconductor die adjacent the second semiconductor die such that the first corner die is over the first semiconductor die, wherein the first corner die includes a first corner die first side, a first corner die second side and a first corner die corner side connecting the first corner die first side and the first corner die second side.

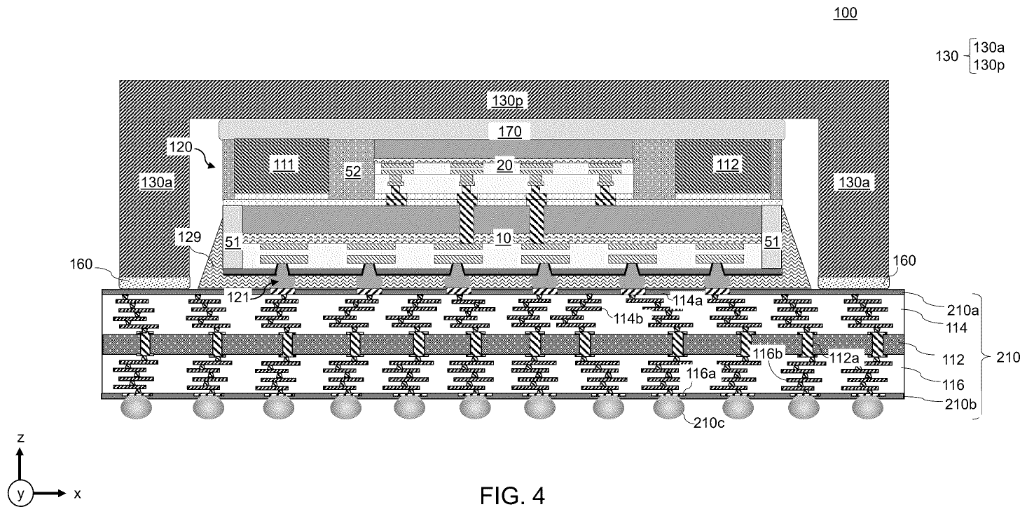

FIG. 4 is a vertical cross-sectional view of a package structure 100 including the semiconductor module 120 according to one more embodiments.

As illustrated in FIG. 4, the package structure 100 may include a package substrate 210 and the semiconductor module 120 on the package substrate 210. The package structure 100 may also include a package lid 130 on the semiconductor module 120. The package lid 130 may include a package lid foot portion 130a attached to the package substrate 210. The package lid 130 may also include a package lid plate portion 130p connected to the package lid foot portion 130a. The package structure 100 may also include a TIM layer 170 between the semiconductor module 120 and the package lid plate portion 130p.

The package substrate 210 may include a cored or coreless substrate. In at least one embodiment, for example, the package substrate 210 may include a core 115, a package substrate upper dielectric layer 117 formed on the core 115 (e.g., a first side or chip-side of the package substrate 210), and a package substrate lower dielectric layer 116 formed on the core 115 (e.g., a second side or board-side of the package substrate 210). In particular, the package substrate 210 may include a build-up film substrate such as an Ajinomoto build-up film (ABF) substrate. That is, in at least one embodiment, each of the package substrate upper dielectric layer 117 and the package substrate lower dielectric layer 116 may be described as an ABF layer.

The core 115 may help to provide rigidity to the package substrate 210. The core 115 may include, for example, an epoxy resin such as a bismaleimide triazine epoxy (BT epoxy) and/or a woven glass laminate. The core 115 may alternatively or in addition include an organic material such as a polymer material. In particular, the core 115 may include a dielectric polymer material such as polyimide (PI), benzocyclo-butene (BCB) polymer, or polybenzobisoxazole (PBO). Other suitable dielectric materials are within the contemplated scope of disclosure.

The core 115 may include one or more through vias 115a. The through vias 115a may extend from a lower surface of the core 115 to an upper surface of the core 115. The through vias 115a may allow an electrical connection between the package substrate upper dielectric layer 117 and the package substrate lower dielectric layer 116. The through vias 115a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 117 may be formed on an upper surface of the core 115. The package substrate upper dielectric layer 117 may include a plurality of layers and, in particular, may include a build-up film (e.g., ABF). The package substrate upper dielectric layer 117 may also include an organic material such as a polymer material. In particular, the package substrate upper dielectric layer 117 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 117 may include one or more package substrate upper bonding pads 117a on a chip-side surface of the package substrate upper dielectric layer 117. The package substrate upper bonding pads 117a may be exposed on the chip-side surface of the package substrate upper dielectric layer 117. The package substrate upper dielectric layer 117 may also include one or more metal interconnect structures 117b. The metal interconnect structures 117b may electrically couple the package substrate upper bonding pads 117a to the through vias 115a in the core 115. The metal interconnect structures 117b may include metal layers (e.g., copper traces) and metal vias connecting the metal layers. The package substrate upper bonding pads 117a and the metal interconnect structures 117b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 210a may be formed on the chip-side surface of the package substrate upper dielectric layer 117. The package substrate upper passivation layer 210a may at least partially cover the package substrate upper bonding pads 117a. The upper passivation layer 210a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 115. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. The package substrate lower dielectric layer 116 may also include one or more metal interconnect structures 116b. The metal interconnect structures 116b may electrically couple the package substrate lower bonding pads 116a to the through vias 115a in the core 115. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 210b may be formed on the board-side surface of the package substrate lower dielectric layer 116. The package substrate lower passivation layer 210b may at least partially cover the package substrate lower bonding pads 116a. The package substrate lower passivation layer 210b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 210c may be formed on the board-side surface of the package substrate 210. The solder balls 210c may allow the package structure 100 to be securely mounted on a substrate such as a printed circuit board (PCB) and electrically coupled to the PCB substrate. The solder balls 210c may contact the package substrate lower bonding pads 116a, respectively. The solder balls 210c may therefore be electrically connected to the package substrate upper bonding pads 114a by way of metal interconnect structures 116b, the through vias 112a and the metal interconnect structures 114b. The solder balls 210c of the BGA may be formed in a two-dimensional array on the board-side surface of the package substrate 210. The solder balls 210c may be located, for example, under the package lid foot portion 130a and under the semiconductor module 120.

As illustrated in FIG. 4, the package substrate 210 may have a width in the x-direction that is greater than a width of the semiconductor module 120 in the x-direction. The package substrate 210 may also have a length in the y-direction that is greater than a length of the semiconductor module 120 in the y-direction. The semiconductor module 120 may be located in a central portion of the package substrate 210.

The semiconductor module 120 may be attached by the C4 bumps 121 to the package substrate upper bonding pads 114a in the package substrate 210. The C4 bumps 121 may include a metal pillar (not shown) and a solder bump (e.g., SnAg solder bump) on the metal pillar. The solder bump may be collapsed to join the metal pillar of the C4 bump 121 to the package substrate upper bonding pads 114a.

A package underfill layer 129 may be formed on the package substrate 210 under and around the semiconductor module 120. The package underfill layer 129 may also be formed around the C4 bumps 121. The package underfill layer 129 may thereby securely fix the semiconductor module 120 to the package substrate 210. The package underfill layer 129 may be formed of an underfill material such as an epoxy-based polymeric material. Other suitable materials may be used for the package underfill layer 129.

The TIM layer 170 may be located on the semiconductor module 120. The TIM layer 170 may include one or more layers. In at least one embodiment, a center of the TIM layer 170 may be substantially aligned with a center of the semiconductor module 120. In at least one embodiment, the TIM layer 170 may extend laterally (e.g., in the x-y plane) beyond the outer sidewall 127a of the second gap fill layer 52.

The TIM layer 170 may have a low bulk thermal impedance and high thermal conductivity. The TIM layer 170 may cover an entire area of the upper surface of the semiconductor module 120. The TIM layer 170 may be attached to the upper surface of the semiconductor module 120 by a thermally conductive adhesive.

In at least one embodiment, the TIM layer 170 may include one or more metals. The TIM layer 170 may include, for example, a low-melting-temperature (LMT) metal TIM or liquid metal TIM. The TIM layer 170 may include one or more metals such as indium, tin, gallium, silver, etc. The TIM layer 170 may include, for example, a gallium base, indium base, silver base, solder base, etc. The solder base may include tin and one or more other elements such as copper, silver, bismuth, indium, zinc, antimony, etc.

The TIM layer 170 may alternatively or additionally include a thermal grease, a thermal paste, thermal film, thermal adhesive, thermal gap filler, thermal pad (e.g., silicone), thermal tape or a gel-type TIM (e.g., a cross-linked polymer film). In at least one embodiment, the TIM layer 170 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 170 are within the contemplated scope of this disclosure.

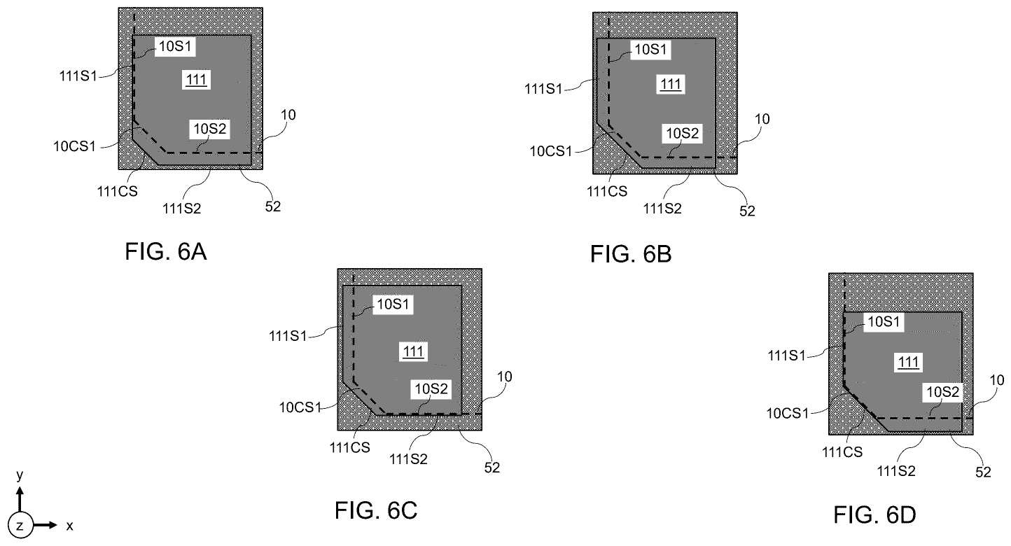

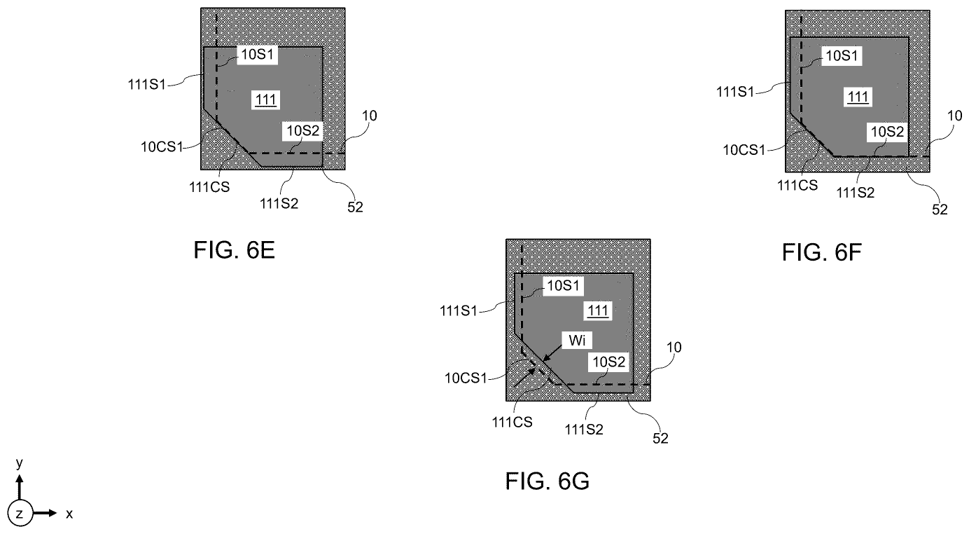

As further illustrated in FIG. 6, the package lid 130 may be located on the TIM layer 170 and may provide a cover for the semiconductor module 120. The package lid 130 may be formed, for example, of metal, ceramic or polymer material. Other suitable materials of the package lid 130 may be used.

The package lid foot portion 130a of the package lid 130 may be attached to the package substrate 210. The package lid foot portion 130a may extend in a substantially perpendicular direction from the package lid plate portion 130p. The package lid foot portion 130a may be connected to the package substrate 210 by an adhesive layer 160. The adhesive layer 160 may include, for example, epoxy adhesive or silicone adhesive. Other adhesives are within the contemplated scope of this disclosure.

The package lid plate portion 130p (e.g., main body of the package lid 130) may be connected to the package lid foot portion 130a (e.g., an upper end of the package lid foot portion 130a). In at least one embodiment, the package lid plate portion 130p may be integrally formed as a unit with the package lid foot portion 130a. The package lid plate portion 130p may alternatively be formed separate from the package lid foot portion 130a and attached to the package lid foot portion 130a by an adhesive (not shown). The adhesive may be substantially similar to the adhesive layer 160 described above.

The package lid plate portion 130p may have a plate-shape extending, for example, in an x-y plane in FIG. 4. An outer periphery of the package lid plate portion 130p may be substantially aligned with an outer periphery of the package lid foot portion 130a. The package lid plate portion 130p may be substantially parallel to an upper surface of the package substrate 210. The package lid plate portion 130p may include a central region that is formed over the semiconductor module 120. In at least one embodiment, a center point (in the x-y plane) of the central region may be substantially aligned with the center point of the semiconductor module 120 and/or with the center point of the TIM layer 170.

The package substrate 210 may have a substantially rectangular shape having a length in the x-direction greater than the width in y-direction. The package substrate 210 may alternatively have a substantially square shape. Each of the package lid foot portion 130a and semiconductor module 120 may have an outer shape that is substantially the same as an outer shape of the package substrate 210. Other shapes of the package substrate 210, package lid 130 and semiconductor module 120 are within the contemplated scope of disclosure. The semiconductor module 120 may be arranged in a central portion of the package substrate 210 so that a space between the semiconductor module 120 and the package lid foot portion 130a is substantially uniform around the perimeter of the semiconductor module 120.

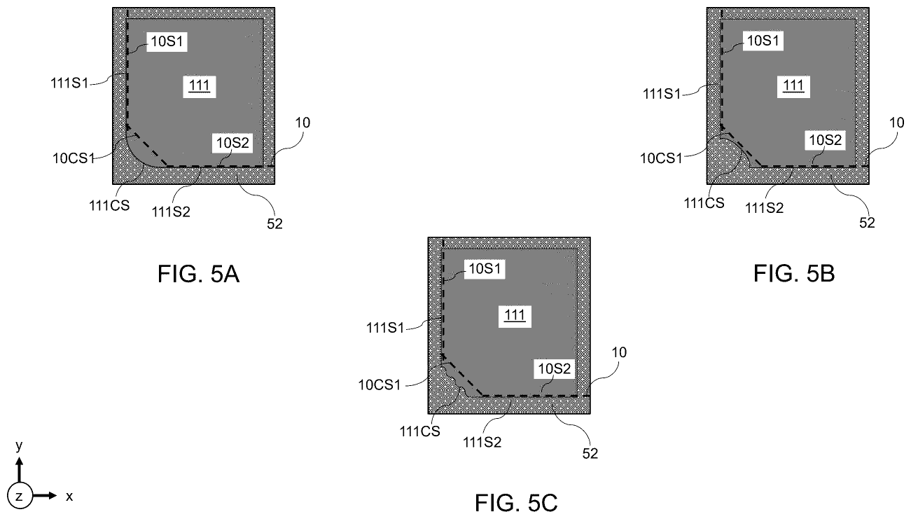

FIGS. 5A-5C are plan views (e.g., top down views) of the first corner die 111 having a first corner die corner side 111CS with an alternative design according to one or more embodiments. It should be noted that the alternative designs in FIGS. 5A-5C may apply not only to the first corner die 111 but to all of the corner dies 110. It should also be noted that in FIGS. 5A-5C, the first corner die first side 111S1 may be substantially aligned with the first semiconductor die first side 10S1 and the first corner die second side 111S2 may be substantially aligned with the first semiconductor die second side 10S2. However, other embodiments may include sides of the first corner die 111 that do not align with the sides of the first semiconductor die 10. That is, the first corner die first side 111S1 may be located outside the first semiconductor die first side 10S1 and/or the first corner die second side 111S2 may be located outside the first semiconductor die second side 10S2.

In particular, FIG. 5A is a plan view of the first corner die 111 having a first corner die corner side 111CS with a convex shape (round shape, curved shape, semicircular shape, etc.) according to one or more embodiments. FIG. 5B is a plan view of the first corner die 111 having a first corner die corner side 111CS with a concave shape according to one or more embodiments. FIG. 5C is a plan view of the first corner die 111 having a first corner die corner side 111CS with a wavy shape (e.g., undulating shape) according to one or more embodiments.

FIGS. 6A-6G are plan views (e.g., top down views) of the first corner die 111 having an alternative design according to one or more embodiments. It should be noted that the alternative designs in FIGS. 6A-6G may apply not only to the first corner die 111 but to all of the corner dies 110 (i.e., 112, 113, 114). It should also be noted that in the semiconductor module 120, at least one side of the first corner die 111 may be located outside the respective side of the first semiconductor die 10. That is, in the semiconductor module 120, at least one of the first corner die first side is outside the first semiconductor die first side, the first corner die second side is outside the first semiconductor die second side, or the first corner die corner side is outside the first semiconductor die first corner side.

In particular, FIG. 6A is a plan view of the first corner die 111 having a first alternative design according to one or more embodiments. As illustrated in FIG. 6A, in the first alternative design, the first corner die first side 111S1 may be substantially aligned with the first semiconductor die first side 10S1, the first corner die corner side 111CS may be located outside the first semiconductor die first corner side 10CS1, and the first corner die second side 111S2 may be located outside the first semiconductor die second side 10S2.

FIG. 6B is a plan view of the first corner die 111 having a second alternative design according to one or more embodiments. As illustrated in FIG. 6B, in the second alternative design, the first corner die first side 111S1 may be located outside the first semiconductor die first side 10S1, the first corner die corner side 111CS may be located outside the first semiconductor die first corner side 10CS1, and the first corner die second side 111S2 may be located outside the first semiconductor die second side 10S2.

FIG. 6C is a plan view of the first corner die 111 having a third alternative design according to one or more embodiments. As illustrated in FIG. 6C, in the third alternative design, the first corner die first side 111S1 may be located outside the first semiconductor die first side 10S1, the first corner die corner side 111CS may be located outside the first semiconductor die first corner side 10CS1, and the first corner die second side 111S2 may be substantially aligned with the first semiconductor die second side 10S2.

FIG. 6D is a plan view of the first corner die 111 having a fourth alternative design according to one or more embodiments. As illustrated in FIG. 6D, in the fourth alternative design, the first corner die first side 111S1 may be substantially aligned with the first semiconductor die first side 10S1, the first corner die corner side 111CS may be substantially aligned with the first semiconductor die first corner side 10CS1, and the first corner die second side 111S2 may be located outside the first semiconductor die second side 10S2.

FIG. 6E is a plan view of the first corner die 111 having a fifth alternative design according to one or more embodiments. As illustrated in FIG. 6E, in the fifth alternative design, the first corner die first side 111S1 may be located outside the first semiconductor die first side 10S1, the first corner die corner side 111CS may be substantially aligned with the first semiconductor die first corner side 10CS1, and the first corner die second side 111S2 may be located outside the first semiconductor die second side 10S2.

FIG. 6F is a plan view of the first corner die 111 having a sixth alternative design according to one or more embodiments. As illustrated in FIG. 6F, in the sixth alternative design, the first corner die first side 111S1 may be located outside the first semiconductor die first side 10S1, the first corner die corner side 111CS may be substantially aligned with the first semiconductor die first corner side 10CS1, and the first corner die second side 111S2 may be substantially aligned with the first semiconductor die second side 10S2.

FIG. 6G is a plan view of the first corner die 111 having a seventh alternative design according to one or more embodiments. As illustrated in FIG. 6G, in the seventh alternative design, the first corner die first side 111S1 may be located outside the first semiconductor die first side 10S1, the first corner die corner side 111CS may be located inside the first semiconductor die first corner side 10CS1, and the first corner die second side 111S2 may be located outside the first semiconductor die second side 10S2. In the seventh alternative design, the first corner die corner side 111CS may be separated from the first semiconductor die first corner side 10CS1 by a distance Wi less than 1000 μm.

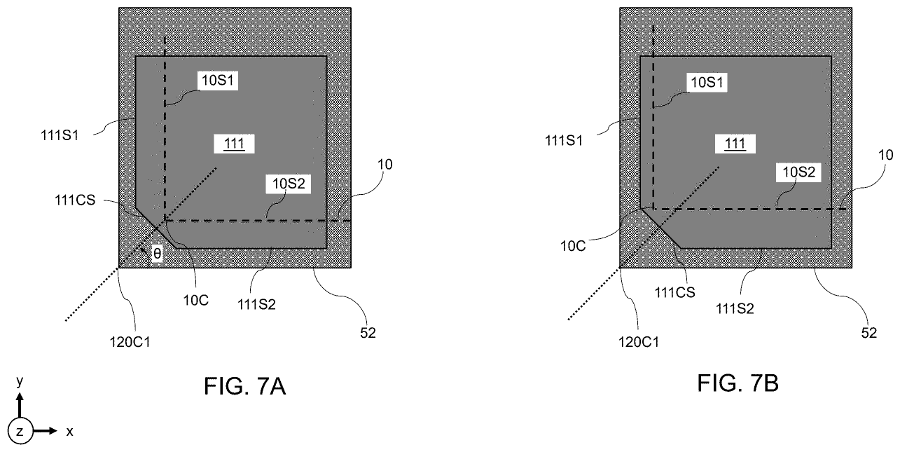

FIG. 7A is a plan view of the first corner die 111 having a first alternative arrangement with the first semiconductor die 10 according to one or more embodiments. As illustrated in FIG. 7A, in the first alternative arrangement, the first semiconductor die 10 may include a right angle corner 10C (e.g., square corner). The first semiconductor die first side 10S1 may intersect the first semiconductor die second side 10S2 to form the right angle corner 10C. The first corner die 111 is over the right angle corner 10C. In particular, the first corner die corner side 111CS may be located outside the right angle corner 10C in the x-direction and/or y-direction.

Further, as further illustrated in FIG. 7A, right angle corner 10C of the first semiconductor die 10 and the first corner die corner side 111CS of the first corner die 111 may be aligned with the first semiconductor module corner 120C1. In particular, as indicated by the dotted line in FIG. 7A, a line intersecting the first semiconductor module corner 120C1 so as to divide the first semiconductor module corner 120C1 into equal 45° portions (θ=45°) may also intersect a center point of the first corner die corner side 111CS and intersect the right angle corner 10C of the first semiconductor die 10.

FIG. 7B is a plan view of the first corner die 111 having a second alternative arrangement with the first semiconductor die 10 according to one or more embodiments. As illustrated in FIG. 7B, in the second alternative arrangement, the first semiconductor die 10 may also include the right angle corner 10C (e.g., square corner) and the first corner die corner side 111CS may be aligned with the first semiconductor module corner 120C1. Further, as in the first alternative arrangement, the first corner die 111 is over the right angle corner 10C. However, in the second alternative arrangement, the right angle corner 10C of the first semiconductor die 10 may not be aligned with the first semiconductor module corner 120C1.

Referring to FIGS. 1A-6G, a semiconductor module 120 may include a first semiconductor die 10, a second semiconductor die 20 on the first semiconductor die 10, and a first corner die 111 adjacent the second semiconductor die 20 on the first semiconductor die 10 and including a first corner die first side 111S1, a first corner die second side 111S2 and a first corner die corner side 111CS connecting the first corner die first side 111S1 and the first corner die second side 111S2, wherein the first corner die 111 may be located over a side of the first semiconductor die 10.

In one embodiment, the side of the first semiconductor die 10 may include a first semiconductor die first side 10S1, a first semiconductor die second side 10S2 and a first semiconductor die first corner side 10CS1 connecting the first semiconductor die first side 10S1 and the first semiconductor die second side 10S2, and at least one of the first corner die first side 111S1 may be outside the first semiconductor die first side 10S1, the first corner die second side 111S2 may be outside the first semiconductor die second side 10S2, or the first corner die corner side 111CS may be outside the first semiconductor die first corner side 10CS1. In one embodiment, the first corner die corner side 111CS may include one of a chamfered shape, a concave shape, a convex shape or a wavy shape. In one embodiment, the first corner die corner side 111CS may include a chamfered shape having a width less than or equal to 7 μm. In one embodiment, the first corner die corner side 111CS may include a chamfered shape and the first semiconductor die first corner side 10CS1 may include a chamfered shape. In one embodiment, the first corner die corner side 111CS may be located outside the first semiconductor die first corner side 10CS1 and an overlap distance Wo between the first corner die corner side 111CS and the first semiconductor die first corner side 10CS1 may be greater than 1 μm. In one embodiment, the first corner die corner side 111CS may be located inside the first semiconductor die first corner side 10CS1 and a distance Wi between the first corner die corner side 111CS and the first semiconductor die first corner side 10CS1 may be less than 1000 μm. In one embodiment, the first corner die first side 111S1 may be substantially aligned with the first semiconductor die first side 10S1 and the first corner die second side 111S2 may be substantially aligned with the first semiconductor die second side 10S2. In one embodiment, the first corner die corner side 111CS may be located outside the first semiconductor die first corner side 10CS1 and at least one of the first corner die first side 111S1 may be located outside the first semiconductor die first side 10S1, or the first corner die second side 111S2 may be located outside the first semiconductor die second side 10S2. In one embodiment, the first corner die corner side 111CS may be substantially aligned with the first semiconductor die first corner side 10CS1 and at least one of the first corner die first side 111S1 may be located outside the first semiconductor die first side 10S1, or the first corner die second side 111S2 may be located outside the first semiconductor die second side 10S2. In one embodiment, the first semiconductor die 10 may further include a first semiconductor die third side 10S3 and a first semiconductor die fourth side 10S4, a first semiconductor die second corner side 10CS2 connecting the first semiconductor die second side 10S2 and the first semiconductor die third side 10S3, a first semiconductor die third corner side 10CS3 connecting the first semiconductor die first side 10S1 and the first semiconductor die fourth side 10S4, and a first semiconductor die fourth corner side 10CS4 connecting the first semiconductor die third side 10S3 and the first semiconductor die fourth side 10S4. In one embodiment, the semiconductor module 120 may further include a second corner die 112 adjacent the second semiconductor die 20 on the first semiconductor die 10 and including a second corner die first side 112S1, a second corner die second side 112S2 and a second corner die corner side 112CS connecting the second corner die first side 112S1 and the second corner die second side 112S2, wherein the second corner die 112 may be located over a side of the first semiconductor die 10, a third corner die 113 adjacent the second semiconductor die 20 on the first semiconductor die 10 and including a third corner die first side 113S1, a third corner die second side 113S2 and a third corner die corner side 113CS connecting the third corner die first side 113S1 and the third corner die second side 113S2, wherein the third corner die 113 may be located over a side of the first semiconductor die 10, and a fourth corner die 114 adjacent the second semiconductor die 20 on the first semiconductor die 10 and including a fourth corner die first side 114S1, a fourth corner die second side 114S2 and a fourth corner die corner side 114CS 114CS connecting the fourth corner die first side 114S1 and the fourth corner die second side 114S2, wherein the fourth corner die 114 may be located over a side of the first semiconductor die 10. In one embodiment, the first corner die corner side 111CS may be located outside the first semiconductor die first corner side 10CS1, the second corner die corner side 112CS may be located outside the first semiconductor die second corner side 10CS2, the third corner die corner side 113CS may be located outside the first semiconductor die third corner side 10CS3, and the fourth corner die corner side 114CS may be located outside the first semiconductor die fourth corner side 10CS4.

Referring again to FIGS. 1A-6G, a method of forming a semiconductor module 120 may include attaching a first semiconductor die 10 to a first carrier substrate 1, forming a backside metal bonding pad 108a on a backside of the first semiconductor die 10, forming a die bonding film 108 on the backside of the first semiconductor die 10 such that the backside metal bonding pad 108a is exposed through the die bonding film 108, attaching a second semiconductor die 20 to the first semiconductor die 10 by a hybrid bond, wherein a frontside metal bonding pad 208a of the second semiconductor die 20 is bonded to the backside metal bonding pad 108a of the first semiconductor die 10 and a second semiconductor die bonding film 208 of the second semiconductor die 20 is bonded to the die bonding film 108, and attaching a first corner die 111 to the first semiconductor die 10 adjacent the second semiconductor die 20 such that the first corner die 111 may be over a side of the first semiconductor die 10, wherein the first corner die 111 includes a first corner die first side 111S1, a first corner die second side 111S2 and a first corner die corner side 111CS connecting the first corner die first side 111S1 and the first corner die second side 111S2.

In one embodiment, the side of the first semiconductor die 10 may include a first semiconductor die first side 10S1, a first semiconductor die second side 10S2 and a first semiconductor die first corner side 10CS1 connecting the first semiconductor die first side 10S1 and the first semiconductor die second side 10S2, and the attaching of the first corner die 111 to the first semiconductor die 10 may include attaching the first corner die 111 to the first semiconductor die 10 such that at least one of the first corner die first side 111S1 is outside the first semiconductor die first side 10S1, the first corner die second side 111S2 is outside the first semiconductor die second side 10S2, or the first corner die corner side 111CS is outside the first semiconductor die first corner side 10CS1. In one embodiment, the method may further include forming the first corner die 111 such that the first corner die corner side 111CS may include one of a chamfered shape, a concave portion or a convex portion. In one embodiment, the method may further include forming the first corner die 111 such that a surface of the first corner die corner side 111CS may include one of a flat surface or a wavy surface. In one embodiment, the method may further include forming the first corner die 111 such that the first corner die corner side 111CS may include a chamfered shape having a length less than or equal to 7 μm. In one embodiment, the side of the first semiconductor die 10 may include a first semiconductor die first side 10S1, a first semiconductor die second side 10S2 and a first semiconductor die first corner side 10CS1 connecting the first semiconductor die first side 10S1 and the first semiconductor die second side 10S2, wherein the first corner die corner side 111CS may include a chamfered shape and the first semiconductor die first corner side 10CS1 may include a chamfered shape, and wherein the attaching of the first corner die 111 to the first semiconductor die 10 may include attaching the first corner die 111 to the first semiconductor die 10 such that one of the first corner die corner side 111CS may be located outside the first semiconductor die first corner side 10CS1 and an overlap distance Wo between the first corner die corner side 111CS and the first semiconductor die first corner side 10CS1 may be greater than 1 μm, or the first corner die corner side 111CS may be located inside the first semiconductor die first corner side 10CS1 and a distance between the first corner die corner side 111CS and the first semiconductor die first corner side 10CS1 may be less than 1000 μm.

Referring again to FIGS. 1A-6G, a package structure 100 may include a package substrate 210, a semiconductor module 120 on the package substrate 210, including a first semiconductor die 10 including a first semiconductor die first corner side 10CS1 including a chamfered shape, a second semiconductor die 20 on the first semiconductor die 10, and a first corner die 111 adjacent the second semiconductor die 20 on the first semiconductor die 10 and including a first corner die corner side 111CS including a chamfered shape and located outside the first semiconductor die first corner side 10CS1 by an overlap distance greater than 1 μm, a thermal interface material (TIM) layer 170 on the semiconductor module 120, and a package lid 130 on the semiconductor module 120 and attached to the package substrate 210, wherein the package lid 130 includes a package lid plate portion 130p on the TIM layer 170 and a package lid foot portion 130a projecting from the package lid plate portion 130p and attached to the package substrate 210.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor module comprising:
a first semiconductor die;
a second semiconductor die on the first semiconductor die; and
a first corner die adjacent to the second semiconductor die on the first semiconductor die and including a first corner die first side, a first corner die second side and a first corner die corner side connecting the first corner die first side and the first corner die second side, wherein the first corner die is located over a side of the first semiconductor die.

2. The semiconductor module of claim 1, wherein the side of the first semiconductor die comprises a first semiconductor die first side, a first semiconductor die second side and a first semiconductor die first corner side connecting the first semiconductor die first side and the first semiconductor die second side, and at least one of:
the first corner die first side is outside the first semiconductor die first side;
the first corner die second side is outside the first semiconductor die second side; or
the first corner die corner side is outside the first semiconductor die first corner side.

3. The semiconductor module of claim 1, wherein the first corner die corner side comprises one of a chamfered shape, a concave shape, a convex shape or a wavy shape.

4. The semiconductor module of claim 1, wherein the first corner die corner side comprises a chamfered shape having a width less than or equal to 7 μm.

5. The semiconductor module of claim 2, wherein the first corner die corner side comprises a chamfered shape and the first semiconductor die first corner side comprises a chamfered shape.

6. The semiconductor module of claim 5, wherein the first corner die corner side is located outside the first semiconductor die first corner side and an overlap distance between the first corner die corner side and the first semiconductor die first corner side is greater than 1 μm.

7. The semiconductor module of claim 5, wherein the first corner die corner side is located inside the first semiconductor die first corner side and a distance between the first corner die corner side and the first semiconductor die first corner side is less than 1000 μm.

8. The semiconductor module of claim 5, wherein the first corner die first side is substantially aligned with the first semiconductor die first side and the first corner die second side is substantially aligned with the first semiconductor die second side.

9. The semiconductor module of claim 5, wherein the first corner die corner side is located outside the first semiconductor die first corner side and at least one of:
the first corner die first side is located outside the first semiconductor die first side; or
the first corner die second side is located outside the first semiconductor die second side.

10. The semiconductor module of claim 5, wherein the first corner die corner side is substantially aligned with the first semiconductor die first corner side and at least one of:
the first corner die first side is located outside the first semiconductor die first side; or
the first corner die second side is located outside the first semiconductor die second side.

11. The semiconductor module of claim 2, wherein the first semiconductor die further comprises:
a first semiconductor die third side and a first semiconductor die fourth side;
a first semiconductor die second corner side connecting the first semiconductor die second side and the first semiconductor die third side;
a first semiconductor die third corner side connecting the first semiconductor die first side and the first semiconductor die fourth side; and
a first semiconductor die fourth corner side connecting the first semiconductor die third side and the first semiconductor die fourth side.

12. The semiconductor module of claim 11, further comprising:
a second corner die adjacent the second semiconductor die on the first semiconductor die and including a second corner die first side, a second corner die second side and a second corner die corner side connecting the second corner die first side and the second corner die second side, wherein the second corner die is located over a side of the first semiconductor die;
a third corner die adjacent the second semiconductor die on the first semiconductor die and including a third corner die first side, a third corner die second side and a third corner die corner side connecting the third corner die first side and the third corner die second side, wherein the third corner die is located over a side of the first semiconductor die; and
a fourth corner die adjacent the second semiconductor die on the first semiconductor die and including a fourth corner die first side, a fourth corner die second side and a fourth corner die corner side connecting the fourth corner die first side and the fourth corner die second side, wherein the fourth corner die is located over a side of the first semiconductor die.

13. The semiconductor module of claim 12, wherein the first corner die corner side is located outside the first semiconductor die first corner side, the second corner die corner side is located outside the first semiconductor die second corner side, the third corner die corner side is located outside the first semiconductor die third corner side, and the fourth corner die corner side is located outside the first semiconductor die fourth corner side.

14. A method of forming a semiconductor module, the method comprising:
attaching a first semiconductor die to a first carrier substrate;
forming a backside metal bonding pad on a backside of the first semiconductor die;
forming a die bonding film on the backside of the first semiconductor die such that the backside metal bonding pad is exposed through the die bonding film;
attaching a second semiconductor die to the first semiconductor die by a hybrid bond, wherein a frontside metal bonding pad of the second semiconductor die is bonded to the backside metal bonding pad of the first semiconductor die and a second semiconductor die bonding film of the second semiconductor die is bonded to the die bonding film; and
attaching a first corner die to the first semiconductor die adjacent the second semiconductor die such that the first corner die is over a side of the first semiconductor die, wherein the first corner die includes a first corner die first side, a first corner die second side and a first corner die corner side connecting the first corner die first side and the first corner die second side.

15. The method of claim 14, wherein the side of the first semiconductor die comprises a first semiconductor die first side, a first semiconductor die second side and a first semiconductor die first corner side connecting the first semiconductor die first side and the first semiconductor die second side, and the attaching of the first corner die to the first semiconductor die comprises attaching the first corner die to the first semiconductor die such that at least one of:
the first corner die first side is outside the first semiconductor die first side;
the first corner die second side is outside the first semiconductor die second side; or
the first corner die corner side is outside the first semiconductor die first corner side.

16. The method of claim 14, further comprising:
forming the first corner die such that the first corner die corner side comprises one of a chamfered shape, a concave portion or a convex portion.

17. The method of claim 14, further comprising:
forming the first corner die such that a surface of the first corner die corner side comprises one of a flat surface or a wavy surface.

18. The method of claim 14, further comprising:
forming the first corner die such that the first corner die corner side comprises a chamfered shape having a length less than or equal to 7 μm.

19. The method of claim 18, wherein the side of the first semiconductor die comprises a first semiconductor die first side, a first semiconductor die second side and a first semiconductor die first corner side connecting the first semiconductor die first side and the first semiconductor die second side, wherein the first corner die corner side comprises a chamfered shape and the first semiconductor die first corner side comprises a chamfered shape, and wherein the attaching of the first corner die to the first semiconductor die comprises attaching the first corner die to the first semiconductor die such that one of:
the first corner die corner side is located outside the first semiconductor die first corner side and an overlap distance between the first corner die corner side and the first semiconductor die first corner side is greater than 1 μm; or
the first corner die corner side is located inside the first semiconductor die first corner side and a distance between the first corner die corner side and the first semiconductor die first corner side is less than 1000 μm.

20. A package structure, comprising:
a package substrate;
a semiconductor module on the package substrate, comprising:
a first semiconductor die including a first semiconductor die first corner side comprising a chamfered shape;
a second semiconductor die on the first semiconductor die; and
a first corner die adjacent the second semiconductor die on the first semiconductor die and including a first corner die corner side comprising a chamfered shape and located outside the first semiconductor die first corner side by an overlap distance greater than 1 μm;
a thermal interface material (TIM) layer on the semiconductor module; and
a package lid on the semiconductor module and attached to the package substrate, wherein the package lid includes a package lid plate portion on the TIM layer and a package lid foot portion projecting from the package lid plate portion and attached to the package substrate.
